(19) United States
(12) Patent Application Publication
(10) Pub. No.: US 2022/0350245 A1
(43) Pub. Date: Nov. 3, 2022

(54) COLORING COMPOSITION, METHOD FOR MANUFACTURING COLORING CURED FILM, COLORING CURED FILM, COLOR FILTER, AND ORGANIC EL DISPLAY DEVICE

(71) Applicant: FUJIFILM Corporation, Tokyo (JP)

(72) Inventor: Keiji YAMAMOTO, Shizuoka (JP)

(73) Assignee: FUJIFILM Corporation, Tokyo (JP)

(21) Appl. No.: 17/853,895

(22) Filed: Jun. 29, 2022

Related U.S. Application Data
(63) Continuation of application No. PCT/JP2021/002576, filed on Jan. 26, 2021.

(30) Foreign Application Priority Data
Feb. 27, 2020 (JP) 2020-031623

(51) Int. Cl. G03F 7/031; C09C 3/06; C09D 4/00; C09D 7/62; C09D 7/63; G02B 5/22; H01L 27/32

(52) U.S. Cl. CPC G03F 7/031; C09C 3/06; C09D 4/00; C09D 7/62; C09D 7/63; G02B 5/223; H01L 27/322

(57) ABSTRACT

A coloring composition is a coloring composition including a black colorant, a polymerizable compound, and a photopolymerization initiator, in which the photopolymerization initiator includes a photopolymerization initiator a in which a light absorption coefficient at 365 nm in methanol is more than 1.0×10² mL/gcm and a photopolymerization initiator b in which a light absorption coefficient at 365 nm in methanol is 1.0×10² mL/gcm or less and a light absorption coefficient at 254 nm is 1.0×10³ mL/gcm or more, a content of the photopolymerization initiator b is 45.0 to 200.0 parts by mass with respect to 100.0 parts by mass of a content of the photopolymerization initiator a, and a ratio of a maximum absorbance to a minimum absorbance of a coloring cured film obtained by curing the coloring composition at a wavelength of 400 to 700 nm is 1.0 to 2.5.

### CROSS-REFERENCE TO RELATED APPLICATIONS

This application is a Continuation of PCT International Application No. PCT/JP2021/002576 filed on Jan. 26, 2021, which claims priority under 35 U.S.C § 119(a) to Japanese Patent Application No. 2020-031623 filed on Feb. 27, 2020. Each of the above application(s) is hereby expressly incorporated by reference, in its entirety, into the present application.

### BACKGROUND OF THE INVENTION

### 1. Field of the Invention

The present invention relates to a coloring composition, a method for manufacturing a coloring cured film, a coloring cured film, a color filter, and an organic EL display device.

### 2. Description of the Related Art

For the purpose of shielding light between colored pixels, enhancing contrast, and the like, a color filter used in a liquid crystal display device includes a light shielding film which is called a black matrix.

In addition, currently, a compact and thin imaging unit is mounted on a mobile terminal of electronic apparatus such as a mobile phone and a personal digital assistant (PDA). A solid-state imaging element such as a charge coupled device (CCD) image sensor and a complementary metal-oxide semiconductor (CMOS) image sensor is provided with a light shielding film for the purpose of preventing the generation of noise, improving image quality, and the like.

For example, JP2004-292672A discloses a “carbon black dispersion liquid which contains carbon Black having an average primary particle diameter of 20 to 30 nm, a DBP absorption amount of 140 ml/100 g or less, and a pH of 2.5 to 4, and an organic compound having an amine value of 1 to 100 mgKOH/g and a weight-average molecular weight of 5000 to 12,000 (claim 1)”.

### SUMMARY OF THE INVENTION

In recent years, a light emitting device of the liquid crystal display device has been changed to an organic EL, and it may be required that a manufacturing process of a member is carried out at a low temperature (for example, 120° C. or lower). In relation to this, it may be required that a black material for a black matrix for suppressing crosstalk of the color filter and a black material for light shielding around pixels can be manufactured without requiring a high temperature treatment.

In a case where a cured film is manufactured by a low temperature process using the black resin composition disclosed in JP2004-292672A, the present inventor has found that a reliability of a coloring cured film (for example, a change in transmittance over time at high temperature and high humidity) tends to be inferior to that of a coloring cured film manufactured through a heat treatment at high temperature. The low temperature process refers to a manufacturing procedure which does not include, for example, a step of heating at higher than 120° C.

Therefore, an object of the present invention is to provide a coloring composition with which a coloring cured film having excellent reliability even in a case where the cured film is manufactured by a low temperature process. Another object of the present invention is to provide a method for manufacturing a coloring cured film, a coloring cured film, a color filter, and an organic EL display device.

As a result of intensive studies, the present inventor has found that the above-described objects can be achieved by the following configurations, and have completed the present invention.

[1]

A coloring composition comprising:
a black colorant;
a polymerizable compound; and
a photopolymerization initiator,
in which the photopolymerization initiator includes a photopolymerization initiator a in which a light absorption coefficient at 365 nm in methanol is more than 1.0×10² mL/gcm and a photopolymerization initiator b in which a light absorption coefficient at 365 nm in methanol is 1.0×10² mL/gcm or less and a light absorption coefficient at 254 nm in methanol is 1.0×10³ mL/gcm or more,
a content of the photopolymerization initiator b is 45.0 to 200.0 parts by mass with respect to 100.0 parts by mass of a content of the photopolymerization initiator a, and
a ratio of a maximum absorbance to a minimum absorbance of a coloring cured film obtained by curing the coloring composition at a wavelength of 400 to 700 nm is 1.00 to 2.50.

[2]

The coloring composition according to [1],
in which the black colorant is one or more kinds selected from the group consisting of a metal nitride, a metal oxynitride, and carbon black.

[3]

The coloring composition according to [1] or [2],
in which the black colorant is surface-coated particles.

[4]

The coloring composition according to any one of [1] to [3],
in which a content of the polymerizable compound is 70 to 250 parts by mass with respect to 100 parts by mass of a content of the black colorant.

[5]

The coloring composition according to any one of [1] to [4],
in which a content of the polymerizable compound is 75 to 200 parts by mass with respect to 100 parts by mass of a content of the black colorant.

[6]

The coloring composition according to any one of [1] to [5],
in which the photopolymerization initiator a is an oxime compound.

[7]

The coloring composition according to any one of [1] to [6],
in which the photopolymerization initiator b is a hydroxyalkylphenone compound.

[8]

The coloring composition according to any one of [1] to [7],
in which the content of the photopolymerization initiator b is 50.0 to 180.0 parts by mass with respect to 100.0 parts by mass of the content of the photopolymerization initiator a.

[9]

The coloring composition according to any one of [1] to [8],
in which the polymerizable compound contains 4 or more ethylenically unsaturated groups.

[10]

The coloring composition according to any one of [1] to [9],
in which the coloring composition is a light-shielding coloring composition used for manufacturing an organic EL display device.

[11]

A method for manufacturing a coloring cured film, comprising:
a composition layer-forming step of applying the coloring composition according to any one of [1] to [10] to a substrate to form a composition layer;
a first exposing step of pre-curing the composition layer by exposing the composition layer to be irradiated with an actinic ray or a radiation; and
a second exposing step of post-curing the composition layer by exposing the pre-cured composition layer to be further irradiated with an actinic ray or a radiation to form a coloring cured film.

[12]

The method for manufacturing a coloring cured film according to [11],
in which the actinic ray or the radiation used for the irradiation in the second exposing step is i-rays, and
an irradiation amount of the i-rays is 1 J/cm² or more.

[13]

The method for manufacturing a coloring cured film according to [11],
in which the actinic ray or the radiation used for the irradiation in the second exposing step is ultraviolet rays.

[14]

The method for manufacturing a coloring cured film according to any one of [11] to [13], further comprising:
a developing step of developing the pre-cured composition layer using a developer to obtain a composition layer having a patterned shape after the first exposing step and before the second exposing step.

[15]

The method for manufacturing a coloring cured film according to any one of [11] to [14], further comprising:
a heating step of heating the coloring cured film after the second exposing step,
in which, in the heating step, the coloring cured film is heated at 100° C. to 120° C. for 10 minutes or longer.

[16]

The method for manufacturing a coloring cured film according to any one of [11] to [15], further comprising:
a heating step of heating the coloring cured film after the second exposing step,
in which the heating step is performed under a nitrogen atmosphere.

[17]

A coloring cured film obtained by curing the coloring composition according to any one of [1] to [10].

[18]

The coloring cured film according to [17],
in which the coloring cured film has a patterned shape. [19]

The color filter comprising:
the coloring cured film according to [17] or [18]; and
one or more subpixels selected from the group consisting of a red subpixel, a green subpixel, and a blue subpixel.

[20]

An organic EL display device comprising:
the color filter according to [19].

According to the present invention, it is possible to provide a coloring composition with which a coloring cured film having excellent reliability even in a case where the cured film is manufactured by a low temperature process. In addition, according to the present invention, it is possible to provide, a method for manufacturing a coloring cured film, a coloring cured film, a color filter, and an organic EL display device.

### BRIEF DESCRIPTION OF THE DRAWINGS

FIG. 1 is a cross-sectional view showing a configuration of an organic EL display device including a coloring cured film according to an embodiment of the present invention.

### DESCRIPTION OF THE PREFERRED EMBODIMENTS

Hereinafter, the present invention will be described in detail.

The description of the configuration requirements described below is made on the basis of representative embodiments of the present invention, but it should not be construed that the present invention is limited to those embodiments.

In the present specification, a numerical range represented using “to” means a range containing numerical values described before and after the preposition “to” as a lower limit value and an upper limit value.

In addition, in a notation for a group (atomic group) in the present specification, in a case where the group is denoted without specifying whether it is substituted or unsubstituted, the group includes both a group having no substituent and a group having a substituent. For example, an “alkyl group” includes not only an alkyl group having no substituent (unsubstituted alkyl group), but also an alkyl group having a substituent (substituted alkyl group).

In addition, “actinic ray” or “radiation” in the present specification means, for example, a bright line spectrum of a mercury lamp such as g-rays, h-rays and i-rays, far ultraviolet rays typified by an excimer laser, extreme ultraviolet rays (EUV light), X-rays, electron beams (EB), or the like. In addition, in the present invention, light means the actinic ray or the radiation.

In addition, unless otherwise specified, “exposure” in the present specification encompasses not only exposure by a bright line spectrum of a mercury lamp, far ultraviolet rays typified by an excimer laser, extreme ultraviolet rays, X-rays, EUV light, or the like, but also drawing by particle beams such as electron beams and ion beams.

In the present specification, “(meth)acrylate” refers to acrylate and methacrylate. In the present specification, “(meth)acrylic” refers to acrylic and methacrylic. In the present specification, “(meth)acryloyl” refers to acryloyl and methacryloyl. In the present specification, “(meth)acrylamide” refers to acrylamide and methacrylamide. In the present specification, “monomeric substance” and “monomer” are synonymous.

In the present specification, “ppm” means “parts per million (10⁻⁶)”, “ppb” means “parts per billion (10⁻⁹)”, “ppt” means “parts per trillion (10⁻¹²)”.

In addition, in the present specification, a weight-average molecular weight (Mw) is a value by a gel permeation chromatography (GPC) method in terms of polystyrene.

In the present specification, the GPC method is based on a method using HLC-8020 GPC (manufactured by Tosoh Corporation), using TSKgel SuperHZM-H, TSKgel SuperHZ4000, and TSKgel SuperHZ2000 (all manufactured by Tosoh Corporation, 4.6 mmID×15 cm) as a column, and using tetrahydrofuran (THF) as an eluent.

The bonding direction of a divalent group (for example, —COO—) denoted in the present specification is not limited unless otherwise specified. For example, in a case where Y in a compound represented by a general formula “X-Y-Z” is —COO—, the compound may be “X-O-CO-Z” or “X-CO-O-Z”.

### [Coloring Composition (Composition)]

A coloring composition (hereinafter, also simply referred to as a “composition”) according to an embodiment of the present invention is a coloring composition including a black colorant, a polymerizable compound, and a photopolymerization initiator, in which the photopolymerization initiator includes a photopolymerization initiator a in which a light absorption coefficient at 365 nm in methanol is more than 1.0×10² mL/gcm and a photopolymerization initiator b in which a light absorption coefficient at 365 nm in methanol is 1.0×10² mL/gcm or less and a light absorption coefficient at 254 nm in methanol is 1.0×10³ mL/gcm or more, and a content of the photopolymerization initiator b is 45.0 to 200.0 parts by mass with respect to 100.0 parts by mass of a content of the photopolymerization initiator a.

In addition, a ratio of a maximum absorbance to a minimum absorbance of a coloring cured film obtained by curing the coloring composition at a wavelength of 400 to 700 nm is 1.00 to 2.50.

A mechanism by which the objects of the present invention can be achieved through the composition having the above-described configuration is not always clear, but is considered to be as follows by the present inventors.

That is, the composition according to the embodiment of the present invention contains the photopolymerization initiator a and the photopolymerization initiator b, which have different absorption characteristics. Therefore, in a case where a coloring cured film (hereinafter, also simply referred to as a “cured film”) is formed by exposing a coating film or the like formed of the composition according to the embodiment of the present invention, first, one photopolymerization initiator is preferentially consumed, and the other photopolymerization initiator is likely to be preserved. Therefore, in the initial stage of the exposure, a reaction is started by the photopolymerization initiator preferentially consumed, and a polymerization proceeds to a certain extent. Further, in a case where the reaction with the preserved photopolymerization initiator proceeds in the subsequent exposure, the finally obtained cured film has a higher degree of polymerization and is excellent in reliability. Such a mechanism can be exhibited without any problem by adjusting a content ratio of the photopolymerization initiator a and the photopolymerization initiator b within a range specified in the present invention, and as a result, the present inventor have considered that a cured film having excellent reliability is obtained without requiring a high temperature treatment.

Hereinafter, the fact that the reliability of the obtained cured film is more excellent is also referred to that the effect of the present invention is excellent.

Hereinafter, components contained in the composition according to the embodiment of the present invention will be described.

A light absorption coefficient and absorbance in the present specification refer to values obtained by measuring an absorbance of light in a wavelength range of 400 to 700 nm in methanol at a concentration of 0.01 g/L using a spectrophotometer (reference: glass substrate) of an ultraviolet-visible-near infrared spectrophotometer UV3600 (manufactured by Shimadzu Corporation).

### [Black Colorant]

The composition according to the embodiment of the present invention contains a black colorant.

In the present specification, the black colorant means a colorant having absorption over the entire wavelength range of 400 to 700 nm.

A content of the black colorant is preferably 5% to 90% by mass, more preferably 10% to 65% by mass, and still more preferably 18% to 38% by mass with respect to the total solid content of the composition.

In the present specification, the “solid content” of the composition refers to components forming a cured film (light shielding film), and refers to all components except a solvent in a case where the composition contains the solvent (an organic solvent, water, or the like). In addition, in a case where a component forms the cured film (light shielding film), the component which is a liquid component is also regarded as a solid content.

Examples of the black colorant include a black pigment and a black dye.

Among these, the black colorant is preferably one or more kinds selected from the group consisting of a metal nitride, a metal oxynitride, and carbon black, and more preferably one or more kinds selected from the group consisting of a metal nitride and a metal oxynitride.

### <Black Pigment>

As the black pigment, various known black pigments can be used. The black pigment may be an inorganic pigment or an organic pigment.

From the viewpoint that light resistance of a light shielding film is more excellent, the black colarant is preferably an inorganic pigment.

As the black pigment, a pigment which expresses black color by itself is preferable, and a pigment which expresses black color by itself and absorbs infrared ray is more preferable.

Here, the black pigment which absorbs infrared ray has absorption in a wavelength region in the infrared region (preferably, a wavelength of 650 to 1300 nm). A black pigment having a maximal absorption wavelength in a wavelength region of 675 to 900 nm is also preferable.

An average primary particle diameter of the black pigment is not particularly limited, but from the viewpoint that balance between handleability and temporal stability (black pigment does not settle) of the composition is more excellent, the average primary particle diameter is preferably 5 to 100 nm, more preferably 5 to 50 nm, and still more preferably 5 to 30 nm.

The average primary particle diameter of the black pigment in the present invention can be measured using a transmission electron microscope (TEM). As the transmission electron microscope, for example, a transmission microscope HT7700 manufactured by Hitachi High-Tech Corporation can be used.

A maximum length (Dmax: maximum length between two points on a contour of a particle image) and a maximum perpendicular length (DV-max: shortest length connecting perpendicularly between two straight lines in a case where the image is interposed between the two straight lines parallel with the maximum length) of a particle image obtained by using the transmission electron microscope are measured, and the geometric mean value (Dmax x DV-max)^{½} thereof is defined as a particle diameter. Particle diameters of 100 particles by the method are measured, and the arithmetic average value thereof is defined as the average primary particle diameter of the particles.

### (Inorganic Pigment)

The inorganic pigment is not particularly limited as long as particles have light shielding properties and contain an inorganic compound, and a known inorganic pigment can be used.

Examples of the inorganic pigment include a metal oxide, a metal nitride, and a metal oxynitride, and it is preferable to be one or more kinds selected from the group consisting of Group 4 metal elements such as titanium (Ti) and zirconium (Zr), Group 5 metal elements such as vanadium (V) and niobium (Nb), and metal oxides, metal nitrides, and metal oxynitrides containing one or two or more metal elements selected from the group consisting of cobalt (Co), chromium (Cr), copper (Cu), manganese (Mn), ruthenium (Ru), iron (Fe), nickel (Ni), tin (Sn), and silver (Ag).

As the above-described metal oxides, metal nitrides, and metal oxynitrides, particles in which other atoms are further mixed may be used. For example, metal nitride-containing particles further containing an atom selected from Group 13 to 17 elements of the periodic table (preferably, an oxygen atom and/or a sulfur atom) can be used.

A method for producing the above-described metal oxides, metal nitrides, or metal oxynitrides is not particularly limited as long as a black pigment having desired physical properties can be obtained, and a known production method such as a gas phase reaction method can be used. Examples of the gas phase reaction method include an electric furnace method and a thermal plasma method, and from the viewpoint that there are few impurities mixed in, the particle size is easy to match, and productivity is high, a thermal plasma method is preferable.

The above-described black pigment such as a metal nitride, a metal oxide, and a metal oxynitride may be surface-coated. That is, the black colorant may be surface-coated particles. The coating may be performed in the entire surface of the particles or a part thereof. The coating is preferably performed with a silane coupling agent, silica, or alumina.

Among these, from the viewpoint that occurrence of undercut in a case of forming the light shielding film can be suppressed, nitrides or oxynitrides of one or more metals selected from the group consisting of titanium, vanadium, zirconium, and niobium are more preferable. In addition, from the viewpoint that moisture resistance of the light shielding film is more excellent, oxynitrides of one or more metals selected from the group consisting of titanium, vanadium, zirconium, and niobium are still more preferable, and titanium nitride, titanium oxynitride (titanium black), zirconium nitride, or zirconium oxynitride is particularly preferable. The above-described nitride or oxynitride of one or more metals selected from the group consisting of titanium, vanadium, zirconium, and niobium may further include an element selected from Na, Mg, K, Ka, Rb, Cs, Hf, Ta, Cr, Mo, W, Mn, Fe, Ru, Os, Co, Ni, Pd, Pt, Cu, Ag, Au, Zn, In, Cl, Br, and I. A content of the above-described element is preferably 0.001% to 5% by mass with respect to the total mass of the nitride or oxynitride of metal.

It is also preferable to use titanium black including an Si atom.

As the titanium black, titanium black described in paragraphs 0122 to 0129 of WO2018/139186A can be used. The same applies to the preferred range.

Examples of the inorganic pigment include carbon black.

Examples of the carbon black include furnace black, channel black, thermal black, acetylene black, and lamp black.

As the carbon black, carbon black manufactured by a known method such as an oil furnace method may be used, or a commercially available product may be used. Specific examples of the commercially available product of the carbon black include organic pigments such as C. I. Pigment Black 1 and inorganic pigments such as C. I. Pigment Black 7.

As the carbon black, surface-treated carbon black is preferable. By the surface treatment, a particle surface state of the carbon black can be reformed, and dispersion stability in the composition can be improved. Examples of the surface treatment include a coating treatment with a resin, a surface treatment for introducing an acidic group, and a surface treatment with a silane coupling agent.

As the carbon black, carbon black coated with a resin is preferable. By coating the surface of the carbon black particles with an insulating resin, light shielding properties and insulating properties of the light shielding film can be improved. In addition, reliability of the image display device can be improved by reducing leakage current and the like. Therefore, it is suitable for applications in which the light shielding film is required to have insulating properties.

Examples of the coating resin include an epoxy resin, polyamide, polyamidoimide, a novolac resin, a phenol resin, a urea resin, a melamine resin, polyurethane, a diallyl phthalate resin, an alkylbenzene resin, polystyrene, polycarbonate, polybutylene terephthalate, and modified polyphenylene oxide.

From the viewpoint that light shielding properties and insulating properties of the light shielding film are more excellent, a content of the coating resin is preferably 0.1% to 40% by mass and more preferably 0.5% to 30% by mass with respect to the total of the carbon black and the coating resin.

### (Organic Pigment)

The organic pigment is not particularly limited as long as particles have light shielding properties and contain an organic compound, and a known organic pigment can be used.

In the present invention, examples of the organic pigment include a bisbenzofuranone compound, an azomethine compound, a perylene compound, and an azo-based compound. Among these, a bisbenzofuranone compound or a perylene compound is preferable.

Examples of the bisbenzofuranone compound include the compounds described in JP2010-534726A, JP2012-515233A, and JP2012-515234A, and the like. The bisbenzofuranone compound is available, for example, as “Irgaphor Black” (trade name) manufactured by BASF.

Examples of the perylene compound include the compounds described in JP1987-1753A (JP-S62-1753A) and JP1988-26784B (JP-S63-26784B). The perylene compound is available as C. I. Pigment Black 21, 30, 31, 32, 33, and 34.

### <Black Dye>

As the black dye, a dye which expresses black color by itself can be used, and for example, a pyrazoleazo compound, a pyrromethene compound, an anilinoazo compound, a triphenylmethane compound, an anthraquinone compound, a benzylidene compound, an oxonol compound, a pyrazolotriazoleazo compound, a pyridoneazo compound, a cyanine compound, a phenothiazine compound, a pyrrolopyrazoleazomethine compound, and the like can be used.

In addition, as the black dye, compounds described in JP1989-90403A (JP-S64-90403A), JP1989-91102A (JP-S64-91102A), JP1989-94301A (JP-H1-94301A), JP1994-11614A (JP-H6-11614A), JP2592207B, U.S. Pat. Nos. 4,808,501A, 5,667,920A, 505,950A, JP1993-333207A (JP-H5-333207A), JP1994-35183A (JP-H6-35183A), JP1994-51115A (JP-H6-51115A), JP1994-194828A (JP-H6-194828A), and the like can be referred to, the contents of which are incorporated herein by reference.

Specific examples of these black dyes include dyes defined by Color Index (C. I.) of solvent black 3, 5, and 27 to 47, and a dye defined by C. I. of solvent black 3, 27, 29, or 34 is preferable.

In addition, examples of a commercially available product of these black dyes include dyes such as Spiron Black MH and Black BH (both manufactured by Hodogaya Chemical Co., Ltd.), VALIFAST Black 3804, 3810, 3820, and 3830 (all manufactured by ORIENT CHEMICAL INDUSTRIES CO., LTD.), Savinyl Black RLSN (manufactured by Clariant), and KAYASET Black K-R and K-BL (both manufactured by Nippon Kayaku Co., Ltd.).

In addition, as the black dye, a coloring agent multimer may be used. Examples of the coloring agent multimer include compounds described in JP2011-213925A and JP2013-041097A. In addition, a polymerizable dye having a polymerizable property in the molecule may be used, and examples of a commercially available product thereof include RDW series manufactured by FUJIFILM Wako Pure Chemical Corporation.

Further, as described above, a plurality of dyes having a color other than black alone may be combined and used as the black dye. As such coloring dye, for example, in addition to dyes of chromatic colors such as R (red), G (green), and B (blue) (chromatic dyes), dyes described in paragraphs 0027 to 0200 of JP2014-42375A can also be used.

### [Photopolymerization Initiator]

The composition according to the embodiment of the present invention contains a photopolymerization initiator.

The above-described photopolymerization initiator contains a photopolymerization initiator a and a photopolymerization initiator b, which will be described later.

For example, the photopolymerization initiator (photopolymerization initiator a, photopolymerization initiator b, and/or the like described later) may be a photoradical polymerization initiator or may be a photocationic polymerization initiator.

A content of the photopolymerization initiator in the composition is preferably 1% to 60% by mass, more preferably 3% to 20% by mass, and still more preferably 5% to 15% by mass with respect to the total solid content of the composition.

The total content of the photopolymerization initiator a and the photopolymerization initiator b is preferably 30% to 100% by mass, more preferably 60% to 100% by mass, and still more preferably 95% to 100% by mass with respect to the total mass of the photopolymerization initiator.

A content of the photopolymerization initiator a is preferably 1.0% to 40% by mass, more preferably 3.0% to 15% by mass, and still more preferably 4.0% to 10% by mass with respect to the total solid content of the composition.

A content of the photopolymerization initiator b is preferably 1.0% to 40% by mass, more preferably 3.0% to 11% by mass, and still more preferably 5.0% to 11% by mass with respect to the total solid content of the composition.

The content of the photopolymerization initiator b is 45.0 to 200.0 parts by mass with respect to 100.0 parts by mass of the content of the photopolymerization initiator a, and from the viewpoint that the effect of the present invention is more excellent, the content thereof is preferably 50.0 to 180.0 parts by mass and more preferably 60.0 to 180.0 parts by mass.

The photopolymerization initiator a and/or photopolymerization initiator b may be used alone or in combination of two or more kinds thereof

<Photopolymerization Initiator a>

The photopolymerization initiator a is a photopolymerization initiator in which a light absorption coefficient at 365 nm in methanol is more than 1.0×10² mL/gcm.

The light absorption coefficient of the photopolymerization initiator a at 365 nm in methanol is preferably more than 1.0×10² mL/gcm and 1.0×10⁴ mL/gcm or less, more preferably 1.0×10³ to 1.0×10⁴ mL/gcm, still more preferably 2.0×10³ to 9.0×10³ mL/gcm, and particularly preferably 6.0×10³ to 8.0×10³ mL/gcm.

The photopolymerization initiator a is preferably an oxime compound, an aminoacetophenone compound, or an acylphosphine compound, and more preferably an oxime compound.

More specifically, for example, the aminoacetophenone-based initiator described in JP1998-291969A (JP-H10-291969A) or the acylphosphine oxide-based initiator described in JP4225898B can also be used.

As the oxime compound, the compound described in JP2001-233842A, the compound described in JP2000-80068A, or the compound described in JP2006-342166A can be used.

The oxime compound is preferably a compound represented by General Formula (OX-1). In the oxime compound, a N—O bond in an oxime may be an (E) isomer, a (Z) isomer, or a mixture of an (E) isomer and a (Z) isomer.

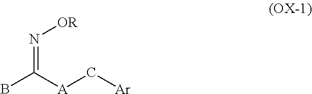

In General Formula (OX-1), R and B each independently represent a monovalent substituent. A represents a divalent organic group. Ar represents an aryl group. C represents —S— or —NR^{N}—. R^{N} represents a hydrogen atom or a monovalent substituent.

In General Formula (OX-1), the monovalent substituents represented by R and R^{N} are each independently preferably a monovalent non-metal atomic group.

Examples of the above-described monovalent non-metal atomic group include an alkyl group, an aryl group, an acyl group, an alkoxycarbonyl group, an aryloxycarbonyl group, a heterocyclic group, an alkylthiocarbonyl group, and an arylthiocarbonyl group. In addition, these groups may have one or more substituents. Furthermore, each of the substituents may be further substituted with another substituent.

Examples of the substituent include a halogen atom, an aryloxy group, an alkoxycarbonyl group or an aryloxycarbonyl group, an acyloxy group, an acyl group, an alkyl group, and an aryl group.

The alkyl group is preferably an alkyl group having 1 to 30 carbon atoms, and specifically, paragraph 0025 of JP2009-191061A can be referred to, the contents of which are incorporated herein by reference.

The aryl group is preferably an aryl group having 6 to 30 carbon atoms, and specifically, paragraph 0026 of JP2009-191061A can be referred to, the contents of which are incorporated herein by reference.

The acyl group is preferably an acyl group having 2 to 20 carbon atoms, and specifically, paragraph 0033 of JP2009-191061A can be referred to, the contents of which are incorporated herein by reference.

The alkoxycarbonyl group is preferably an alkoxycarbonyl group having 2 to 20 carbon atoms, and specifically, paragraph 0034 of JP2009-191061A can be referred to, the contents of which are incorporated herein by reference.

The aryloxycarbonyl group is preferably an aryloxycarbonyl group having 6 to 30 carbon atoms, and paragraph 0035 of JP2009-191061A can be referred to, the contents of which are incorporated herein by reference.

The heterocyclic group is preferably an aromatic or aliphatic hetero ring including a nitrogen atom, an oxygen atom, a sulfur atom, or a phosphorus atom.

Specifically, paragraph 0037 of JP2009-191061A can be referred to, the contents of which are incorporated herein by reference.

The alkylthiocarbonyl group is preferably an alkylthiocarbonyl group having 1 to 20 carbon atoms, and paragraph 0038 of JP2009-191061A can be referred to, the contents of which are incorporated herein by reference.

The arylthiocarbonyl group is preferably an arylthiocarbonyl group having 6 to 30 carbon atoms, and paragraph 0039 of JP2009-191061A can be referred to, the contents of which are incorporated herein by reference.

In General Formula (OX-1), the monovalent substituent represented by B is preferably an alkyl group (preferably having 1 to 30 carbon atoms), an aryl group, a heterocyclic group, an arylcarbonyl group, or a heterocyclic carbonyl group. In addition, these groups may have one or more substituents. Examples of the substituents include the aforementioned substituents. Furthermore, each of the substituents may be further substituted with another sub stituent.

Among these, the monovalent substituent represented by B is preferably a group described in paragraph 0044 of JP2009-191061A, the contents of which are incorporated herein by reference.

In Formula (OX-1) described above, the divalent organic group represented by A is preferably a carbonyl group, an alkylene group having 1 to 12 carbon atoms, a cycloalkylene group, an alkynylene group, an arylene group having 6 to 15 carbon atoms, or a group consisting of a combination of these groups. In addition, these groups may have one or more substituents if possible. Examples of the substituents include the aforementioned substituents. Furthermore, each of the substituents may be further substituted with another substituent.

In Formula (OX-1) described above, the aryl group represented by Ar is preferably an aryl group having 6 to 30 carbon atoms, and the aryl group may have a substituent. As the substituent, a group same as the substituent introduced into the substituted aryl group mentioned above as specific examples of the aryl group which may have a substituent can be exemplified.

Among these, from the viewpoint of increasing sensitivity and suppressing coloration with time of heating, the aryl group represented by Ar is preferably a substituted or unsubstituted phenyl group or naphthyl group.

In a case where A is an arylene group having 6 to 15 carbon atoms, Ar and A may be further bonded to each other through a group other than C to form a ring. Examples of the above-described group other than C include a single bond or a divalent linking group.

In a case where C in Formula (OX-1) is —S—, as a preferred structure of “SAr” formed by Ar in Formula (OX-1) and S adjacent thereto, the description in paragraph 0049 of JP2009-191061A can be referred to, the contents of which are incorporated herein by reference.

As the oxime compound, the description in paragraphs 0050 to 0106 of JP2009-191061A, the contents of which are incorporated herein by reference.

Among these, the oxime compound is preferably 1,2-octanedione, 1-[4-(phenylthio)-,2-(O-benzoyloxime)] (for example, Irgacure OXE01), or ethanone, 1-[9-ethyl-6-(2-methylbenzoyl)-9H-carbazol-3-yl] 1-(O-acetyloxime) (for example, Irgacure OXE02).

In addition, the oxime compound is also preferably a compound represented by General Formula (I-1).

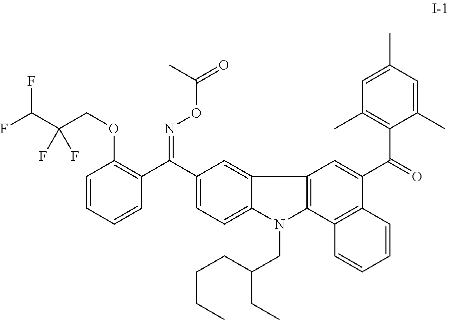

As the aminoacetophenone compound, Omnirad 369 and Omnirad 379 (trade names; both manufactured by IGM Resins B.V.), which are commercially available products, can be used.

As the aminoacetophenone compound, the compound which is described in JP2009-191179A and whose absorption wavelength is matched to a light source having a long wavelength such as 365 nm or 405 nm can also be used.

In addition, as the acylphosphine compound, Omnirad 819 (trade name; manufactured by IGM Resins B.V) which is a commercially available product can be used.

The photopolymerization initiator a is preferably 2-benzyl-2-dimethylamino-1-(4-morpholinophenyl)-butanone-1 (for example, Omnirad 369), 2-dimethylamino-2-(4-methyl-benzyl)-1-(4-moliphorin-4-yl-phenyl)-butane-1-one (for example, Omnirad 379), bis(2,4,6-trimethylbenzoyl)-phenylphosphine oxide (for example, Omnirad 819), 1,2-octanedione, 1-[4-(phenylthio)-,2-(O-benzoyloxime)] (for example, Irgacure OXE01), ethanone, 1-[9-ethyl-6-(2-methylbenzoyl)-9H-carbazol-3-yl]-, 1-(0-acetyloxime) (for example, Irgacure OXE02), or the compound represented by General Formula (I-1) described above.

Among these, 1,2-octanedione, 1-[4-(phenylthio)-,2-(O-benzoyloxime)] (for example, Irgacure OXE01), ethanone, 1-[9-ethyl-6-(2-methylbenzoyl)-9H-carbazol-3-yl]-, 1-(0-acetyloxime) (for example, Irgacure OXE02), or the compound represented by General Formula (I-1) described above is preferable.

<Photopolymerization Initiator b>

The photopolymerization initiator b is a photopolymerization initiator in which a light absorption coefficient at 365 nm in methanol is 1.0×10² mL/gcm or less and a light absorption coefficient at 254 nm in methanol is 1.0×10³ mL/gcm or more.

The light absorption coefficient of the photopolymerization initiator b at 365 nm in methanol is preferably 10 to 1.0×10² mL/gcm, and more preferably 20 to 9.0×10′ mL/gcm.

The light absorption coefficient of the photopolymerization initiator b at 254 nm in methanol is preferably 1.0×10³ to 1.0×10⁶ mL/gcm, and more preferably 5.0×10³ to 1.0 10⁵ mL/gcm.

A difference in light absorption coefficient at a wavelength of 365 nm in methanol between the photopolymerization initiator a and the photopolymerization initiator b is 9.0×10² mL/gcm or more, preferably 9.0×10² to 1.0×10⁵ mL/gcm and more preferably 9.0×10² to 1.0×10⁴ mL/gcm.

The photopolymerization initiator b is preferably a hydroxyacetophenone compound, an aminoacetophenone compound, or an acylphosphine compound, and more preferably a hydroxyacetophenone compound.

More specifically, for example, the aminoacetophenone-based initiator described in JP1998-291969A (JP-H10-291969A) or the acylphosphine oxide-based initiator described in JP4225898B can also be used.

The hydroxyacetophenone compound is preferably a compound represented by Formula (V).

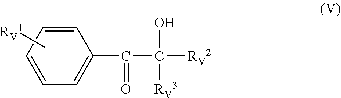

In Formula (V), Rv¹ represents a hydrogen atom, an alkyl group (preferably, an alkyl group having 1 to 10 carbon atoms), an alkoxy group (preferably, an alkoxy group having 1 to 10 carbon atoms), or a divalent organic group. In a case where Rv¹ is a divalent organic group, the compound represents a dimer consisting of two photoactive hydroxyacetophenone structures (that is, a structure in which the substituent Rv¹ is excluded from the compound represented by General Formula (V)) through Rv¹.

Rv² and Rv³ each independently represent a hydrogen atom or an alkyl group (preferably, an alkyl group having 1 to 10 carbon atoms). In addition, Rv² and Rv³ may be bonded to each other to form a ring (preferably, a ring having 4 to 8 carbon atoms).

The alkyl group and alkoxy group as Rv¹ described above, the alkyl group as Rv² and Rv³, and the ring formed by bonding Rv² and Rv³ may further have a substituent.

Examples of the photopolymerization initiator b include 1-hydroxy-cyclohexyl-phenyl-ketone (for example, Omnirad 184), 2-hydroxy-2-methyl-1-phenyl-propan-1-one (for example, Darocur 1173), 1-[4-(2-hydroxyethoxy)-phenyl]-2-hydroxy-2-methyl-1-propan-1-one (for example, Omnirad 2959), oxy-phenyl-acetic acid 2-[2-oxo-2-phenyl-acetoxy-ethoxy]-ethyl ester (for example, Omnirad 754), and phenyl glyoxylic acid methyl ester (for example, Darocur MBF).

Among these, one or more kinds selected from the group consisting of 1-hydroxy-cyclohexyl-phenyl-ketone and 1-[4-(2-hydroxyethoxy)-phenyl]-2-hydroxy-2-methyl-1-propan-1-one are preferable.

### [Polymerizable Compound]

The composition according to the embodiment of the present invention contains a polymerizable compound.

In the present specification, the polymerizable compound is a compound which is polymerized by an action of the photopolymerization initiator, which will be described later, and is a component different from resins such as a dispersant and an alkali-soluble resin.

The polymerizable compound is preferably a low-molecular-weight compound. The low-molecular-weight compound referred to here is preferably a compound having a molecular weight of 3000 or less.

A content of the polymerizable compound in the composition is not particularly limited, but is preferably 1% to 65% by mass, more preferably 10% to 55% by mass, and even more preferably 20% to 45% by mass with respect to the total solid content of the composition.

From the viewpoint that the effect of the present invention is more excellent, the content of the polymerizable compound is preferably 70 to 250 parts by mass, more preferably 75 to 200 parts by mass, and still more preferably 82 to 150 parts by mass with respect to 100 parts by mass of the content of the black colorant.

The polymerizable compound may be used alone, or in combination of two or more kinds thereof. In a case where two or more kinds of polymerizable compounds are used, it is preferable that the total content thereof is within the above-described range.

The polymerizable compound is preferably a compound containing an ethylenically unsaturated group as a curable group.

That is, the composition according to the embodiment of the present invention preferably contains, as the polymerizable compound, a low-molecular-weight compound containing an ethylenically unsaturated group.

The polymerizable compound is preferably a compound containing one or more ethylenically unsaturated bonds such as a (meth)acryloyl group, more preferably a compound containing two or more ethylenically unsaturated bonds, still more preferably a compound containing three or more ethylenically unsaturated bonds, and particularly preferably a compound containing four or more ethylenically unsaturated bonds. The upper limit is, for example, 15 or less.

The polymerizable compound is preferably a compound represented by Formula (Z-6).

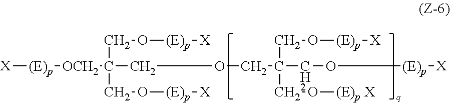

In Formula (Z-6), E's each independently represent —(CH₂)_{y}—CH₂—O—, —(CH₂)_{y}—CH(CH₃)—O—, —(CH₂)_{y}—CH₂—CO—O—, —(CH₂)_{y}—CH(CH₃)—CO—O—, —CO—(CH₂)_{y}—CH₂—O—, —CO—(CH₂)_{y}—CH(CH₃)—O—, —CO—(CH₂)_{y}—CH₂—CO—O—, or —CO—(CH₂)_{y}—CH(CH₃)—CO—O—. For these groups, it is preferable that a bonding position on the right side is a bonding position on the X side.
y's each independently represent an integer of 1 to 10.
X's each independently represent a (meth)acryloyl group or a hydrogen atom.
p's each independently represent an integer of 0 to 10.
q represents an integer of 0 to 3.

In Formula (Z-6), the total number of (meth)acryloyl groups is preferably (3+2q) or (4+2q).
p is preferably an integer of 0 to 6, and more preferably an integer of 0 to 4.

The total of each p is preferably 0 to (40+20q), more preferably 0 to (16+8q), and still more preferably 0 to (12+6q).

In addition, as the polymerizable compound, a compound in which q in Formula (Z-6) is 0 and one of the four groups represented by “—O—(E)ₚ—X” is replaced with a methyl group may be used.

As the polymerizable compound, for example, compounds described in paragraph 0050 of JP2008-260927A, paragraph 0040 of JP2015-68893A, paragraph 0227 of JP2013-29760A, and paragraphs 0254 to 0257 of JP2008-292970A can also be used.

### [Resin]

It is also preferable that the composition according to the embodiment of the present invention contains a resin.

A molecular weight of the resin is more than 3000. In a case where a molecular weight distribution of the resin is polydisperse, a weight-average molecular weight thereof is more than 3000.

A content of the resin in the composition is preferably 3% to 65% by mass, more preferably 7% to 55% by mass, and still more preferably 12% to 45% by mass with respect to the total solid content of the composition.

In a case where two or more kinds of resins are used in combination, the total content thereof is preferably within the above-described range.

The resin also preferably contains an acid group (for example, a carboxyl group, a sulfo group, a monosulfate ester group, —OPO(OH)2, a monophosphate ester group, a borate group, a phenolic hydroxyl group, and/or the like).

The resin also preferably contains a curable group. Examples of the curable group include an ethylenically unsaturated group (for example, a (meth)acryloyl group, a vinyl group, a styryl group, and the like), and a cyclic ether group (for example, an epoxy group, an oxetanyl group, and the like).

The resin of the present invention may be any of a dispersant, an alkali-soluble resin, or the like.

### <Dispersant>

The dispersant is, for example, is a resin which can suppress aggregation and/or sedimentation of components present in the composition in a solid state, such as a pigment.

A content of the dispersant is preferably 1% to 40% by mass, more preferably 3% to 25% by mass, and still more preferably 7% to 17% by mass with respect to the total solid content of the composition.

The dispersant preferably contains an acid group.

The dispersant also preferably contains a curable group.

Examples of the dispersant include a resin which contains a structural unit containing a graft chain and a resin which contains a radial structure.

Examples of the structural unit containing a graft chain in the resin which contains a structural unit containing a graft chain include a structural unit represented by any of Formulae (1) to (4).

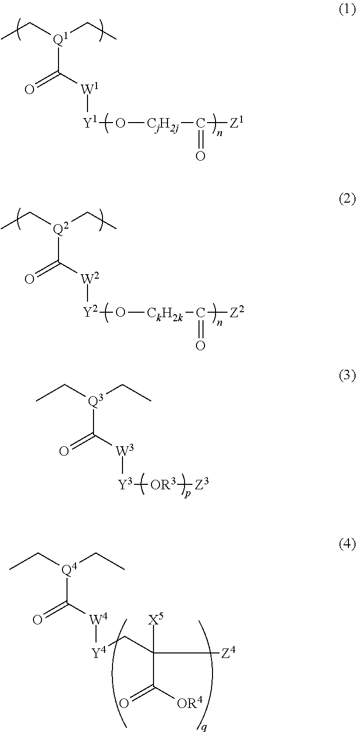

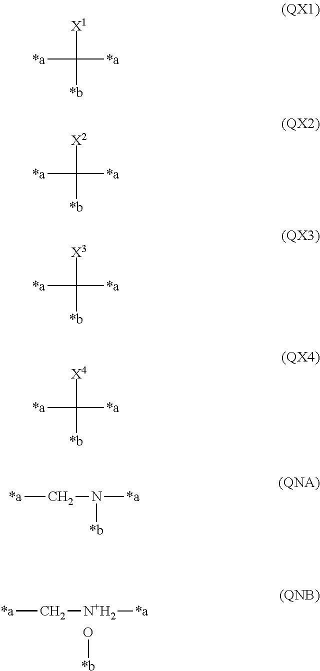

In Formulae (1) to (4), Q¹ is a group represented by any of Formula (QX1), (QNA), or (QNB), Q² is a group represented by any of Formula (QX2), (QNA), or (QNB), Q³ is a group represented by any of Formula (QX3), (QNA), or (QNB), and Q⁴ is a group represented by any of Formula (QX4), (QNA), or (QNB).

In Formulae (QX1) to (QX4), (QNA), and (QNB), *a represents a bonding position on the main chain side, and *b represents a bonding position on the side chain side.

In Formulae (1) to (4), W¹, W², W³, and W⁴ each independently represent a single bond, an oxygen atom, or NH.

In Formulae (1) to (4) and (QX1) to (QX4), X¹, X², X³, X⁴, and X⁵ each independently represent a hydrogen atom or a monovalent organic group. From the viewpoint of restriction on synthesis, X¹, X², X³, X⁴, and X⁵ are each independently preferably a hydrogen atom or an alkyl group having 1 to 12 carbon atoms (the number of carbon atoms), more preferably a hydrogen atom or a methyl group, and still more preferably a methyl group.

In Formulae (1) to (4), Y¹, Y²Y³, and Y⁴ each independently represent a single bond or a divalent linking group, and the linking group is not particularly limited on a structure. Specific examples of the divalent linking groups represented by Y¹, Y², Y³, and Y⁴ include linking groups represented by the following (Y-1) to (Y-23).

In the linking groups shown below, A represents a bonding position with any of W¹ to W⁴ in Formulae (1) to (4). B represents a bonding position with the group on the opposite side of any of W¹ to W⁴ to which A is bonded.

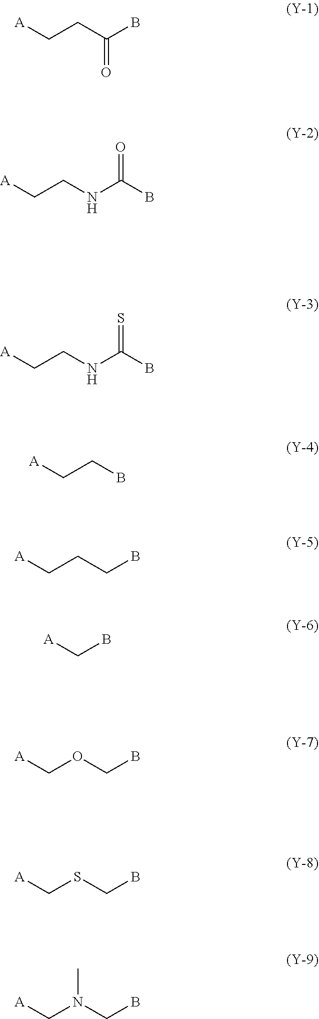

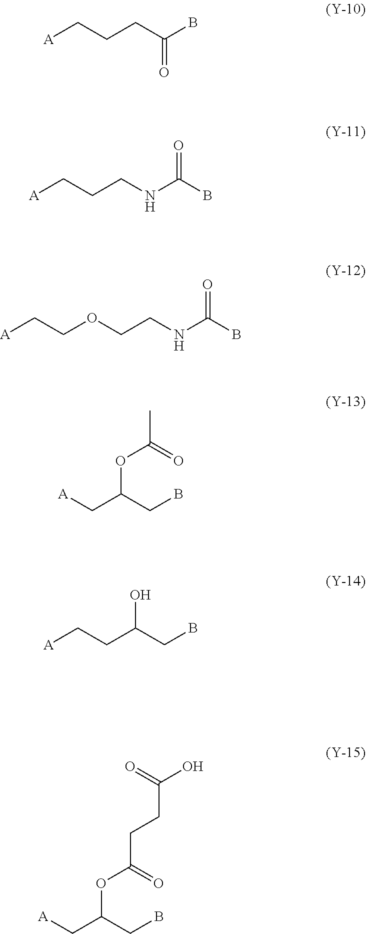

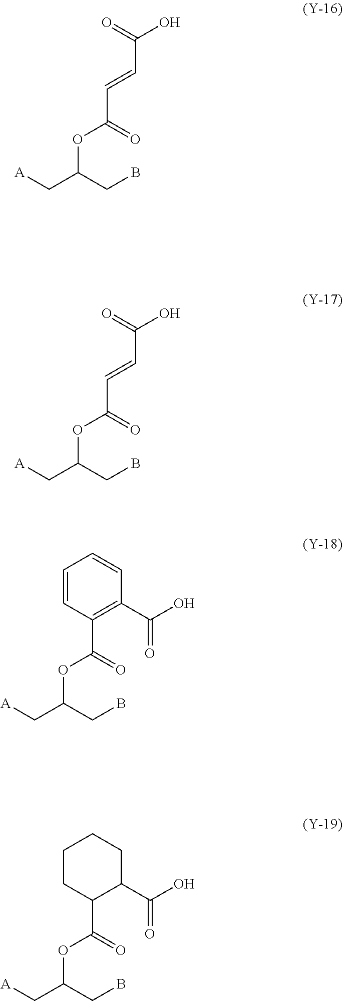

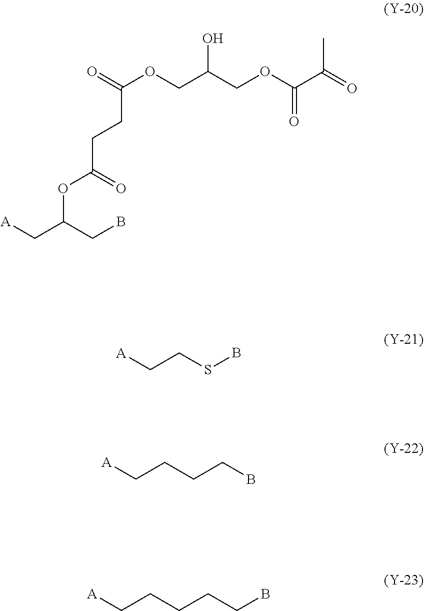

In Formulae (1) to (4), Z¹, Z², Z³, and Z⁴ each independently represent a monovalent substituent. A structure of the substituent is not particularly limited, and specific examples thereof include an alkyl group, a hydroxyl group, an alkoxy group, an aryloxy group, a heteroaryloxy group, an alkylthio group, an arylthio group, a heteroarylthio group, and an amino group.

Among these, particularly from the viewpoint of improvement in the dispersibility, the substituents represented by Z¹, Z², Z³, and Z⁴ are each independently preferably a group exhibiting a steric repulsion effect, and more preferably an alkyl group or alkoxy group having 5 to 24 carbon atoms, and among these, in particular, still more preferably a branched alkyl group having 5 to 24 carbon atoms, a cyclic alkyl group having 5 to 24 carbon atoms, or an alkoxy group having 5 to 24 carbon atoms. An alkyl group included in the alkoxy group may be linear, branched, or cyclic.

In addition, it is also preferable that the substituents represented by Z¹, Z², Z³, and Z⁴ are each a group containing a curable group such as a (meth)acryloyl group. Examples of the above-described group containing a curable group include an “—O-alkylene group-(—O-alkylene group-)_{AL}-(meth)acryloyloxy group”. AL represents an integer of 0 to 5, and is preferably 1. The above-described alkylene groups preferably each independently have 1 to 10 carbon atoms. In a case where the above-described alkylene group has a substituent, the substituent is preferably a hydroxyl group.

The above-described substituent may be a group containing an onium structure.

The group containing an onium structure is a group having an anionic moiety and a cationic moiety. Examples of the anionic moiety include a partial structure containing an oxygen anion (—O⁻). Among these, the oxygen anion (—O⁻) is preferably directly bonded to a terminal of a repeating structure attached with n, m, p, or q in the repeating units represented by Formulae (1) to (4), and more preferably directly bonded to a terminal (that is, a right end in —(—O—CⱼH₂ⱼ—CO—)ₙ—) of a repeating structure attached with n in the repeating unit represented by Formula (1).

Examples of a cation of the cationic moiety of the group containing an onium structure include an ammonium cation. In a case where the cationic moiety is the ammonium cation, the cationic moiety is a partial structure containing a cationic nitrogen atom (>N⁺<). The cationic nitrogen atom (>N⁺<) is preferably bonded to four substituents (preferably, organic groups), and it is preferable that one to four among the substituents are each an alkyl group having 1 to 15 carbon atoms. In addition, it is also preferable that one or more (preferably, one) among the four sub stituents are each the group containing a curable group. Examples of the above-described group containing a curable group, which can be the above-described sub stituent, include the above-described “—O-alkylene group-(—O-alkylene group-)_{AL}-(meth)acryloyloxy group”.

In Formulae (1) to (4), n, m, p, and q are each independently an integer of 1 to 500, more preferably an integer of 2 to 500, and more preferably an integer of 6 to 500.

In Formula (3), R³ represents a branched or linear alkylene group, and is preferably an alkylene group having 1 to 10 carbon atoms and more preferably an alkylene group having 2 or 3 carbon atoms.

In Formula (4), R⁴ represents a hydrogen atom or a monovalent organic group, and the structure of the monovalent organic group is not particularly limited. R⁴ is preferably a hydrogen atom, an alkyl group, an aryl group, or a heteroaryl group, and more preferably a hydrogen atom or an alkyl group. In a case where R⁴ is an alkyl group, the alkyl group is preferably a linear alkyl group having 1 to 20 carbon atoms, a branched alkyl group having 3 to 20 carbon atoms, or a cyclic alkyl group having 5 to 20 carbon atoms.

The total content of the structural unit represented by any of Formulae (1) to (4) in the resin which contains a structural unit containing a graft chain is preferably 2% to 100% by mass and more preferably 6% to 100% by mass with respect to the total mass of the above-described resin.

As the dispersant, for example, polymer compounds described in paragraphs 0071 to 0141 of WO2019/069690A can also be used.

As the dispersant, a commercially available product may be used, and examples thereof include DISPERBYK series (DISPERBYK-167 and the like) manufactured by BYK Chemie.

### <Alkali-Soluble Resin>

The alkali-soluble resin is, for example, a resin which can be soluble in a basic solution such as a basic aqueous solution.

The alkali-soluble resin is preferably a resin different from the above-described dispersant.

A content of the alkali-soluble resin is preferably 0.1% to 45% by mass, more preferably 0.5% to 35% by mass, and still more preferably 4% to 25% by mass with respect to the total solid content of the composition.

The alkali-soluble resin preferably contains an acid group as an alkali-soluble group for achieving alkali solubility.

The alkali-soluble resin also preferably contains a curable group. The alkali-soluble resin also preferably contains a structural unit containing a curable group. A content of the structural unit containing a curable group is preferably 5 to 60 mol %, more preferably 10 to 45 mol %, and still more preferably 15 to 35 mol % with respect to all structural units of the alkali-soluble resin.

As the alkali-soluble resin, a copolymer of [benzyl (meth)acrylate/(meth)acrylic acid/other addition-polymerizable vinyl monomers as necessary], or a copolymer of [allyl (meth)acrylate/(meth)acrylic acid/other addition-polymerizable vinyl monomers as necessary] is suitable because the copolymers have an excellent balance among film hardness, sensitivity, and developability.

The above-described other addition-polymerizable vinyl monomers may be used alone or in combination of two or more thereof.

From the viewpoint that the moisture resistance of the light shielding film is more excellent, the above-described copolymer preferably has a curable group and more preferably contains an ethylenically unsaturated group such as a (meth)acryloyl group.

For example, a curable group may be introduced into a copolymer by using a monomer having the curable group as the above-described other addition-polymerizable vinyl monomers. In addition, a curable group (preferably, an ethylenically unsaturated group such as a (meth)acryloyl group) may be introduced into a part of or all of one or more units derived from (meth)acrylic acid and/or units derived from the above-described other addition-polymerizable vinyl monomers in the copolymer.

As the alkali-soluble resin, for example, resins described in paragraphs 0143 to 0163 of WO2019/069690A can be used.

Weight-average molecular weights of the resin such as the dispersant and the alkali-soluble resin are each independently preferably more than 3000 and 100000 or less, and more preferably more than 3000 and 50000 or less.

Acid values of the resin such as the dispersant and the alkali-soluble resin are each independently preferably 10 to 300 mgKOH/g, and more preferably 30 to 200 mgKOH/g.

Amine values of the resin such as the dispersant and the alkali-soluble resin are each independently preferably 0 to 100 mgKOH/g, and more preferably 0 to 25 mgKOH/g.

The dispersant preferably satisfies one of ranges of the above-described acid value and the above-described amine value, and preferably satisfies both.

### [Dispersion Aid]

The composition may contain a dispersion aid.

The dispersion aid is a component other than the above-described resins, and is a component which can suppress aggregation and/or sedimentation of components present in the composition in a solid state, such as a pigment.

Examples of the dispersion aid include a pigment derivative.

A content of the dispersion aid is preferably 0.01% to 10% by mass, more preferably 0.1% to 8% by mass, and still more preferably 0.3% to 4% by mass with respect to the total solid content of the composition.

### [Ultraviolet Absorber]

The composition according to the embodiment of the present invention may contain an ultraviolet absorber.

A content of the ultraviolet absorber is preferably 0.01% to 10% by mass, more preferably 0.1% to 8% by mass, and still more preferably 1% to 6% by mass with respect to the total solid content of the composition.

Examples of the ultraviolet absorber include a conjugated diene compound, and the ultraviolet absorber may be a compound represented by Formula (I).

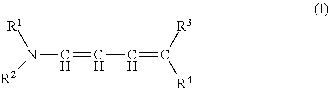

In Formula (I), R¹ and R² each independently represent a hydrogen atom, an alkyl group having the number of carbon atoms of 1 to 20, or an aryl group having the number of carbon atoms of 6 to 20, and R¹ and R² may be the same as or different from each other, provided that both of R¹ and R² do not represent a hydrogen atom at the same time.

In Formula (I), R³ and R⁴ each independently represent an electron withdrawing group. The above-described electron withdrawing group is an electron withdrawing group having a Hammett's substituent constant σₚ value of 0.20 to 1.0.

The description of R¹ to R⁴ in the ultraviolet absorber represented by Formula (I) can be referred to the description of paragraphs 0024 to 0033 of WO2009/123109A (paragraphs 0040 to 0059 of the corresponding US2011/0039195A), the contents of which are incorporated herein by reference. As the compound represented by Formula (I), the description of exemplary compounds (1) to (14) of paragraphs 0034 to 0037 of WO2009/123109A (paragraph 0060 of the corresponding US2011/0039195A) can be referred to, the contents of which are incorporated herein by reference.

### [Polymerization Inhibitor]

The composition may contain a polymerization inhibitor.

As the polymerization inhibitor, for example, a known polymerization inhibitor can be used. Examples of the polymerization inhibitor include phenol-based polymerization inhibitors (for example, p-methoxyphenol, 2,5-di-tert-butyl-4-methylphenol, 2,6-di-tert-butyl-4-methylphenol, 4,4′-thiobis (3-methyl-6-t-butylphenol), 2,2′-methylenebis(4-methyl-6-t-butylphenol), 4-methoxynaphthol, and the like); hydroquinone-based polymerization inhibitor (for example, hydroquinone, 2,6-di-tert-butyl hydroquinone, and the like); quinone-based polymerization inhibitors (for example, benzoquinone and the like); free radical polymerization inhibitors (for example, 2,2,6,6-tetramethylpiperidine 1-oxyl free radical, 4-hydroxy-2,2,6,6-tetramethylpiperidine 1-oxyl free radical, and the like); nitrobenzene-based polymerization inhibitors (for example, nitrobenzene, 4-nitrotoluene, and the like); and phenothiazine-based polymerization inhibitors (for example, phenothiazine, 2-methoxyphenothiazine, and the like).

Among these, from the viewpoint that the composition has more excellent effects, a phenol-based polymerization inhibitor or a free radical-based polymerization inhibitor is preferable.

In a case where the polymerization inhibitor is used together with the resin containing a curable group, the effect thereof is remarkable.

A content of the polymerization inhibitor in the composition is preferably 0.0001% to 0.5% by mass, more preferably 0.001% to 0.2% by mass, and still more preferably 0.008% to 0.05% by mass with respect to the total solid content of the composition. The polymerization inhibitor may be used singly or in combination of two or more kinds thereof. In a case where two or more kinds of polymerization inhibitors are used in combination, it is preferable that the total content thereof is within the above-described range.

In addition, a ratio (content of polymerization inhibitor/content of polymerizable compound (mass ratio)) of the content of the polymerization inhibitor to the content of the polymerizable compound in the composition is preferably 0.00005 to 0.02 and more preferably 0.0001 to 0.005.

### [Surfactant]

The composition may contain a surfactant. The surfactant contributes to improvement in coating properties of the composition.

In a case where the above-described composition contains a surfactant, a content of the surfactant is preferably 0.001% to 2.0% by mass, more preferably 0.003% to 0.5% by mass, and still more preferably 0.005% to 0.1% by mass with respect to the total solid content of the composition.

The surfactant may be used alone or in combination of two or more thereof. In a case where two or more kinds of surfactants are used in combination, the total amount thereof is preferably within the above-described range.

Examples of the surfactant include a fluorine-based surfactant, a nonionic surfactant, a cationic surfactant, an anionic surfactant, and a silicone-based surfactant.

Examples of the fluorine-based surfactant include MEGAFACE F171, MEGAFACE F172, MEGAFACE F173, MEGAFACE F176, MEGAFACE F177, MEGAFACE F141, MEGAFACE F142, MEGAFACE F143, MEGAFACE F144, MEGAFACE R30, MEGAFACE F437, MEGAFACE F475, MEGAFACE F479, MEGAFACE F482, MEGAFACE F554, MEGAFACE F780, and MEGAFACE F781F (all manufactured by DIC Corporation); FLUORAD FC430, FLUORAD FC431, and FLUORAD FC171 (all manufactured by Sumitomo 3M Limited); SURFLON S-382, SURFLON SC-101, SURFLON SC-103, SURFLON SC-104, SURFLON SC-105, SURFLON SC-1068, SURFLON SC-381, SURFLON SC-383, SURFLON S-393, and SURFLON KH-40 (all manufactured by ASAHI GLASS CO., LTD.); and PF636, PF656, PF6320, PF6520, and PF7002 (all manufactured by OMNOVA Solutions Inc.).

As the fluorine-based surfactant, a block polymer can also be used, and specific examples thereof include compounds described in JP2011-89090A.

### [Solvent]

The composition preferably contains a solvent.

As the solvent, for example, a known solvent can be used.

A content of the solvent in the composition is preferably an amount such that the concentration of solid contents of the composition is 10% to 90% by mass, more preferably an amount such that the concentration of solid contents thereof is 10% to 45% by mass, and still more preferably an amount such that the concentration of solid contents thereof is 17% to 38% by mass. That is, the content of the solvent is preferably 10% to 90% by mass, more preferably 55% to 90% by mass, and still more preferably 62% to 83% by mass with respect to the total mass of the composition.

The solvent may be used singly or in combination of two or more thereof. In a case where two or more kinds of solvents are used in combination, the content thereof is preferably adjusted so that the total solid content of the composition is within the above-described range.

Examples of the solvent include water and an organic solvent.

### <Organic Solvent>

Specific examples of the organic solvent include acetone, methyl ethyl ketone, cyclohexane, ethyl acetate, ethylene dichloride, tetrahydrofuran, toluene, ethylene glycol monomethyl ether, ethylene glycol monoethyl ether, ethylene glycol dimethyl ether, propylene glycol monomethyl ether, propylene glycol monoethyl ether, acetylacetone, cyclohexanone, cyclopentanone, diacetone alcohol, ethylene glycol monomethyl ether acetate, ethylene glycol ethyl ether acetate, ethylene glycol monoisopropyl ether, ethylene glycol monobutyl ether acetate, 3-methoxypropanol, methoxyethanol, diethylene glycol monomethyl ether, diethylene glycol monoethyl ether, diethylene glycol dimethyl ether, diethylene glycol diethyl ether, propylene glycol monomethyl ether acetate, propylene glycol monoethyl ether acetate, 3-methoxypropyl acetate, N,N-dimethylformamide, dimethyl sulfoxide, γ-butyrolactone, butyl acetate, methyl lactate, N-methyl-2-pyrrolidone, and ethyl lactate, but the organic solvent is not limited thereto.

### [Other Optional Components]

The composition may further contain any component other than the above-described components. For example, the composition may or may not contain a particulate component other than those described above, a colorant other than black, a silane coupling agent, a sensitizer, a co-sensitizer, a crosslinking agent, a curing accelerator, a thermal curing accelerator, a plasticizer, a diluent, and a sensitization agent, and further, a known additive such as an adhesion promoter to the surface of the substrate and other auxiliary agents (for example, conductive particles, a filler, an antifoaming agent, a flame retardant, a leveling agent, a peeling accelerator, an antioxidant, an aromatic chemical, a surface tension adjuster, a chain transfer agent, and the like).

Regarding these components, reference can be made to, for example, the descriptions in paragraphs 0183 to 0228 of JP2012-003225A (corresponding to paragraphs 0237 to 0309 of US2013/0034812A), paragraphs 0101, 0102, 0103, 0104, and 0107 to 0109 of JP2008-250074A, and paragraphs 0159 to 0184 of JP2013-195480A, the contents of which are incorporated into the specification of the present application.

### [Method for Producing Composition]

The composition can be produced by mixing each of the above-described components.

In a case where the composition contains a black pigment, it is preferable to produce a dispersion liquid in which the black pigment and the like are dispersed, and further mix the obtained dispersion liquid with other components to obtain the composition. In addition, it is also preferable to contain a polymerization inhibitor in the dispersion liquid.

The above-described dispersion liquid can be prepared by mixing each of the above-described components by a known mixing method (for example, a mixing method using a stirrer, a homogenizer, a high-pressure emulsifier, a wet crusher, a wet disperser, or the like).

In a case of preparing the composition, the respective components may be formulated at once, or each of the components may be dissolved or dispersed in a solvent and then sequentially formulated. In addition, the input order and the operation conditions during the formulation are not particularly limited.

For the purpose of removing foreign matters, reducing defects, and the like, the composition is preferably filtered through a filter. As the filter, for example, any filters which have been used in the related art for filtration use and the like may be used without particular limitation. Examples thereof include filters formed of a fluororesin such as polytetrafluoroethylene (PTFE), a polyamide-based resin such as nylon, or a polyolefin-based resin (including a high-density polypropylene and ultrahigh molecular weight polypropylene) such as polyethylene and polypropylene (PP). Among these materials, polypropylene (including a high-density polypropylene) or nylon is preferable.

A pore diameter of the filter is preferably 0.1 to 7.0 μm, more preferably 0.2 to 2.5 μm, even more preferably 0.2 to 1.5 μm, and particularly preferably 0.3 to 0.7 μm. In a case where the pore diameter is within the above range, it is possible to reliably remove fine foreign matters such as impurities and aggregates contained in a pigment while suppressing filtration clogging of the pigment (including the black pigment).

In a case of using a filter, different filters may be combined. In this case, the filtering with a first filter may be performed once or may be performed twice or more times. In a case where filtering is performed twice or more by combining different filters, it is preferable that the pore diameter of the second and subsequent filters are the same or larger than the pore diameter of the first filtering. In addition, first filters having different pore diameters within the above-described range may be combined. With regard to the pore diameter of the filter herein, reference can be made to nominal values of filter manufacturers. A commercially available filter can be selected from, for example, various filters provided by Nihon Pall Corporation, Toyo Roshi Kaisha., Ltd., Nihon Entegris K. K. (formerly Nippon Microlith Co., Ltd.), and Kitz Micro Filter Corporation.

As a second filter, a filter formed of the same material as that of the first filter, or the like can be used. A pore diameter of the second filter is preferably 0.2 to 10.0 μm, more preferably 0.2 to 7.0 μm, and even more preferably 0.3 to 6.0 μm.

It is preferable that the composition does not include impurities such as metals, metal salts containing halogens, acids, and alkalis. The content of impurities included in these materials is preferably 1 ppm by mass or less, more preferably 1 ppb by mass or less, still more preferably 100 ppt by mass or less, particularly preferably 10 ppt by mass or less, and it is most preferable that the impurities are not substantially included (below the detection limit of a measuring device).

Furthermore, the impurities can be measured using an inductively coupled plasma mass spectrometer (manufactured by Agilent Technologies, Inc., Agilent 7500cs model).

The composition according to the embodiment of the present invention is a composition used for manufacturing a cured film, and is preferably light-shielding coloring composition used for manufacturing a light shielding film described later.

The composition according to the embodiment of the present invention is preferably a composition (including a light-shielding coloring composition) used for manufacturing an optical element, a solid-state imaging element, and an image display device (image display device including a color filter containing a cured film, and the like), which will be described later, and more preferably a composition (light-shielding coloring composition) used for manufacturing an organic EL display device (OLED).

### [Manufacturing of Cured Film]

A composition layer formed of the composition according to the embodiment of the present invention is cured to obtain a cured film (including a cured film having a patterned shape). The cured film is preferably a light shielding film.

Hereinafter, a procedure for forming a cured film using the composition as described above will be described.

A method for manufacturing the cured film is not particularly limited, but preferably includes the following steps.
Composition layer-forming step of applying the composition to a substrate to form a composition layer
First exposing step of pre-curing the composition layer by exposing the composition layer to be irradiated with an actinic ray or a radiation
Second exposing step of post-curing the composition layer by exposing the pre-cured composition layer to be further irradiated with an actinic ray or a radiation to form a coloring cured film

The above-described first exposing step is preferably a step of promoting a reaction mainly by one of the photopolymerization initiator a or the photopolymerization initiator b, and the above-described second exposing step is preferably a step of promoting a reaction mainly by the other of the photopolymerization initiator a or the photopolymerization initiator b. It is preferable that the photopolymerization initiator a mainly initiates the reaction in the first exposing step, and it is preferable that the photopolymerization initiator b mainly initiates the reaction in the second exposing step.

A transition from the above-described first exposing step to the above-described second exposing step may be continuously performed without any joint between the two steps, or may be performed through a temporal and/or procedural gap. For example, another step (developing step or the like) may be performed between the above-described first exposing step and the above-described second exposing step. Light sources used in the above-described first exposing step and the above-described second exposing step may be the same or different from each other.

Hereinafter, each of the steps will be described.

### [Composition Layer-Forming Step]

In the composition layer-forming step, the composition is applied to a support or the like to form a layer (composition layer) of the composition prior to exposure. As the support, for example, a substrate (for example, a silicon substrate or a substrate containing an Si atom, such as a glass substrate) or a substrate for a solid-state imaging element, on which an imaging element (light receiving element) such as CCD and CMOS is provided, can be used. In addition, in order to improve adhesion with the upper layer, prevent the diffusion of substances, and planarize the surface of the substrate, an undercoat layer may be provided on the support, as needed.

As a method for applying the composition to the support, various coating methods such as a slit coating method, an ink jet method, a spin coating method, a cast coating method, a roll coating method, and a screen printing method can be applied. A film thickness of the composition layer is preferably 0.1 to 10 μm, more preferably 0.2 to 5 μm, and still more preferably 0.2 to 3 μm. The composition layer applied on the support can be dried (pre-baked), for example, in a hot plate, an oven, or the like at a temperature of 50° C. to 120° C. in 10 to 300 seconds.

### [First Exposing Step]

In the first exposing step, the composition layer (dry film) formed in the composition layer-forming step is exposed by irradiating the composition layer with actinic ray or radiation to pre-cure the light-irradiated composition layer.

The first exposing step may be a patterned exposure or a full exposure.

Among these, a method of light irradiation in the first exposing step is preferably a patterned exposure of irradiating light in a patterned manner, such as through a photo mask having a patterned opening portion.

The exposure is preferably performed by irradiation with radiation. The radiation which can be used for the exposure is preferably ultraviolet rays such as g-ray, h-ray, and i-ray, and a light source is preferably a high-pressure mercury lamp.

Among these, in the first exposing step, it is preferable to expose using light having a wavelength of 330 to 500 nm (for example, i-rays). The light used for the exposure may contain light having a wavelength other than 330 to 500 nm, and in this case, it is preferable that, in a case where an intensity of the maximum wavelength in a wavelength region of 330 to 500 nm is set as 100%, the intensity of the maximum wavelength in a wavelength region of 200 to 315 nm is 10% or less.

The lower limit of an irradiation amount (preferably, an irradiation amount of i-rays) is preferably 0.005 J/cm² or more, more preferably 0.1 J/cm² or more, and still more preferably 1 J/cm² or more. The upper limit thereof is preferably 10 J/cm² or less, more preferably 8 J/cm² or less, and still more preferably 3 J/cm² or less.

In a case where the composition contains a thermal polymerization initiator, the composition layer may be heated in the above-described exposing step.

It is also preferable that the first exposing step and/or the second exposing step described later is performed in an inert gas atmosphere. Examples of the inert gas include nitrogen gas, helium gas, and argon gas. The inert gas may be used alone or in combination of two or more thereof.

A concentration of the inert gas in performing the first exposing step and/or the second exposing step described later is preferably 90% by volume or more, more preferably 95% by volume or more, and still more preferably 99% by volume or more. The upper limit thereof is 100% by volume or less.

It is also preferable that the first exposing step and/or the second exposing step described later is performed in an atmosphere with a low oxygen concentration. The oxygen concentration is preferably 19% by volume or less, more preferably 15% by volume or less, still more preferably 10% by volume or less, particularly preferably 7% by volume or less, and most preferably 3% by volume or less. The lower limit thereof is not particularly limited, but is practically equal to or higher than 10 ppm by volume.

### [Developing Step]

It is also preferable that a developing step is further performed after the first exposing step and before the second exposing step.

The developing step is a step of developing the pre-cured composition layer after the first exposure using a developer to remove a non-exposed portion. By this step, the composition layer of a light-unirradiated portion in the exposing step is eluted, and a patterned composition layer is obtained in which only the pre-cured portion reflects the exposure pattern.

The type of a developer used in the developing step is not particularly limited, but an alkali developer which does not damage the underlying imaging element, circuit, and the like is desirable.

The developing temperature is, for example, 20° C. to 30° C.

The developing time is, for example, 20 to 90 seconds. In recent years, in order to remove the residue better, the development may be performed for 120 to 180 seconds. Furthermore, in order to further improve residue removability, a step of shaking off the developer every 60 seconds and supplying a fresh developer may be repeated several times.

As the alkali developer, an alkaline aqueous solution prepared by dissolving an alkaline compound in water so that the concentration is 0.001% to 10% by mass (preferably, 0.01% to 5% by mass) is preferable.

Examples of the alkaline compound include sodium hydroxide, potassium hydroxide, sodium carbonate, sodium silicate, sodium metasilicate, ammonia water, ethylamine, diethylamine, dimethylethanolamine, tetramethylammonium hydroxide, tetraethylammonium hydroxide, tetrapropylammonium hydroxide, tetrabutylammonium hydroxide, benzyltrimethylammonium hydroxide, choline, pyrrole, piperidine, and 1,8-diazabicyclo[5.4.0]-7-undecene (among these, an organic base is preferable).

Furthermore, in a case where the alkaline compound is used as an alkali developer, the alkaline compound is generally subjected to a washing treatment with water after development.

### [Second Exposing Step]

The second exposing step is a step of post-curing the composition layer by exposing the pre-cured composition layer to be further irradiated with an actinic ray or a radiation to form a cured film.

The composition layer exposed in the second exposing step may be a composition layer in a patterned manner, in which a non-exposed portion is removed by a development treatment. By subjecting the composition layer in a patterned manner to the second exposing step, the obtained cured film is also a patterned cured film.

The second exposing step may be a patterned exposure or a full exposure.

The actinic ray or radiation used for the irradiation in the second exposing step is preferably ultraviolet rays. The above-described ultraviolet rays are preferably ultraviolet rays having a wavelength of 315 nm or less, and more preferably ultraviolet rays having a wavelength of 300 nm or less. In this case, the actinic ray or radiation used for the irradiation in this step may contain light other than ultraviolet rays.

In a case where the ultraviolet rays are irradiated in the second exposing step, in the light irradiated in this step, it is preferable that, in a case where an intensity of the maximum wavelength in a wavelength region of 330 to 500 nm is set as 100%, the intensity of the maximum wavelength in a wavelength region of 200 to 315 nm (preferably, in a wavelength of 200 to 300 nm) is 50% or more.

In addition, an irradiation amount of light irradiated to the composition layer in the second exposing step (preferably, an irradiation amount of the above-described ultraviolet rays) is preferably 0.1 to 20 J/cm², more preferably 0.3 to 10 J/cm², and still more preferably 0.8 to 5 J/cm².

In addition, the actinic ray or radiation used for the irradiation in the second exposing step is also preferably i-rays.

In this case, the actinic ray or radiation used for the irradiation in this step may contain light other than i-rays.

In a case where the i-rays are irradiated in the second exposing step, in the light irradiated in this step, it is preferable that, in a case where an intensity of the maximum wavelength in a wavelength region of 330 to 500 nm is set as 100%, the intensity of the maximum wavelength in a wavelength region of 200 to 315 nm is less than 50%, and it is more preferable to be 10% or less.

The lower limit of an irradiation amount (preferably, an irradiation amount of i-rays) is preferably 0.005 J/cm² or more, more preferably 0.1 J/cm² or more, and still more preferably 1 J/cm² or more. The upper limit thereof is preferably 10 J/cm² or less, more preferably 8 J/cm² or less, and still more preferably 3 J/cm² or less.

### [Heating Step (Post-Baking)]

After the second exposing step, it is also preferable to perform a heating step (post-baking) in which the obtained cured film is heated.

The heating step can be performed continuously or batchwise by using a heating unit such as a hot plate, a convection oven (hot air circulation dryer), and a high-frequency heater.

A heating temperature for heating the cured film in the heating step is preferably 120° C. or lower and more preferably 100° C. to 120° C.

A heating time for heating the cured film in the heating step is preferably 10 minutes or longer and more preferably 10 minutes or longer and shorter than 30 minutes.

The above-described heating temperature is intended to be a temperature reached by the heated cured film. The above-described heating time is intended to be a time for maintaining the cured film at a predetermined heating temperature.

It is also preferable that the above-described heating step is performed in an inert gas atmosphere. Examples of the inert gas include nitrogen gas, helium gas, and argon gas. The inert gas may be used alone or in combination of two or more thereof.

A concentration of the inert gas in performing the above-described heating step is preferably 90% by volume or more, more preferably 95% by volume or more, and still more preferably 99% by volume or more. The upper limit thereof is 100% by volume or less.

The above-described heating step is preferably performed in an atmosphere with a low oxygen concentration. The oxygen concentration is preferably 19% by volume or less, more preferably 15% by volume or less, still more preferably 10% by volume or less, particularly preferably 7% by volume or less, and most preferably 3% by volume or less. The lower limit thereof is not particularly limited, but is practically equal to or higher than 10 ppm by volume.

### [Physical Properties of Cured Film and Application of Cured Film]

### [Physical Properties of Cured Film]

The cured film formed of the composition according to the embodiment of the present invention can be preferably used as a light shielding film.

The cured film may have a patterned shape as described above.

A ratio (maximum absorbance/minimum absorbance) of the maximum absorbance to the minimum absorbance of the cured film at a wavelength of 400 to 700 nm is 1.00 to 2.50, preferably 1.40 to 2.00 and more preferably 1.50 to 2.00. In a case where the ratio of the maximum absorbance to the minimum absorbance is within the above-described range, the cured film can absorb light in the visible light region relatively evenly, and it is easy to be used as a light shielding film.

From the viewpoint that excellent light shielding properties are exhibited, in the cured film, an optical density (OD) per film thickness of 1.5 μm in a wavelength region of 400 to 1200 nm is preferably more than 2.0, more preferably more than 2.5, still more preferably more than 3.0, and particularly preferably more than 3.5. In addition, the upper limit value thereof is not particularly limited, but is preferably 10 or less, in general.

In the present specification, the expression that the optical density per film thickness of 1.5 μm in a wavelength region of 400 to 1200 nm is more than 2.0 means that an optical density per film thickness of 1.5 μm in the entire wavelength region of 400 to 1200 nm is more than 2.0.

In addition, the cured film (light shielding film) preferably has good light shielding properties to light in the infrared region, and for example, an optical density per film thickness of 1.5 μm in light having a wavelength of 940 nm is preferably more than 2.0 and more preferably more than 3.0. In addition, the upper limit value thereof is not particularly limited, but is preferably 10 or less, in general.

In a case where the cured film is used as a light attenuating film, it is preferable that the above-described optical density is smaller than the above-described value.

In the present specification, as a method for measuring the optical density of the cured film, a cured film is first formed on a glass substrate, and using a spectrophotometer (UV-3600 manufactured by Shimadzu Corporation, or the like), the optical density per predetermined film thickness is calculated.

In addition, even in a state of the composition layer (dry film) to which the composition is applied and dried, it is normal that the film thickness and the optical density do not change significantly as compared with a state of the cured film which is subsequently exposed and cured. In such a case, the optical density of the composition layer (dry film) may be measured by the above-described measuring method, and the obtained value may be used as the optical density of the cured film.

The film thickness of the cured film is, for example, preferably 0.1 to 4.0 μm and more preferably 1.0 to 2.5 μm. The cured film may be thinner or thicker than the above range depending on the application.

The “light shielding” using, as a light shielding film, a cured film formed of the composition according to the embodiment of the present invention is a concept that also includes light attenuation in which light passes through the cured film (light shielding film) while being attenuated. In a case where the cured film (light shielding film) is used as the light attenuating film having such a function, the optical density of the cured film may be smaller than the above-described range.

In addition, in a case where the cured film is used as a light attenuating film, the light shielding properties may be adjusted by making the cured film thinner than the above-described range (for example, 0.1 to 0.5 μm). In this case, an optical density per film thickness of 1.0 μm in a wavelength range of 400 to 700 nm (and/or to light having a wavelength of 940 nm) is preferably 0.1 to 1.5 and more preferably 0.2 to 1.0.

A reflectivity of the cured film is preferably less than 8%, more preferably less than 6%, and still more preferably lower than 4%. The lower limit is 0% or more.

The reflectivity referred to here is determined from a reflectivity spectrum obtained by injecting light having a wavelength of 400 to 1100 nm at an incidence angle of 5° using a spectroscope V7200 (trade name) VAR unit manufactured by JASCO Corporation. Specifically, the reflectivity of light having a wavelength showing the maximum reflectivity in the wavelength range of 400 to 1100 nm is defined as the reflectivity of the cured film.

In addition, the above-described cured film is suitable for an optical filter, a light shielding member and a light shielding film of a module, and an antireflection member and an antireflection film, which are used in a product such as portable devices such as a personal computer, a tablet, a mobile phone, a smartphone, and a digital camera; office automation (OA) equipments such as a printer multifunction device and a scanner; industrial equipments such as a surveillance camera, a bar code reader, an automated teller machine (ATM), a high-speed camera, and an equipment with personal authentication functions using face image authentication or biometric authentication; in-vehicle camera equipments; medical camera equipments such as an endoscope, a capsule endoscope, and a catheter; and space equipments such as a biosensor, a biosensor, a military reconnaissance camera, a stereoscopic map camera, a meteorological and oceanographic observation camera, a land resource exploration camera, and an exploration camera for space astronomical and deep space targets.

The cured film can also be used in applications of a micro light emitting diode (LED), a micro organic light emitting diode (OLED), and the like. The cured film is suitable for an optical filter and an optical film used in the micro LED and the micro OLED and for a member which imparts a light-shielding function or an antireflection function.

Examples of the micro LED and micro OLED include examples described in JP2015-500562B and JP2014-533890A.

The above-described cured film is also suitable as an optical filter and optical film used in a quantum dot sensor and a quantum dot solid-state imaging element. In addition, the light shielding film is suitable as a member which imparts a light-shielding function or an antireflection function. Examples of the quantum dot sensor and the quantum dot solid-state imaging element include examples described in US2012/37789A and WO2008/131313A.

### [Light Shielding Film, Optical Element, and Solid-State Imaging Element]

It is also preferable that the cured film according to the embodiment of the present invention is used as a so-called light shielding film. It is also preferable to such a light shielding film for a solid-state imaging element.

As described above, the cured film formed of the composition according to the embodiment of the present invention has excellent light shielding properties and low reflection properties.

The light shielding film is one of the preferred uses in the cured film according to the embodiment of the present invention, and the light shielding film of the present invention can be similarly produced by a method described as the method for manufacturing the cured film. Specifically, the light shielding film can be manufactured by applying the composition to a substrate to form a composition layer, and performing exposure and development on the composition layer.

The present invention also includes an invention of an optical element. The optical element of the present invention is an optical element having the above-described cured film (light shielding film). Examples of the optical element include an optical element used in an optical instrument such as a camera, a binocle, a microscope, and a semiconductor exposure device.

Among these, as the above-described optical element, for example, a solid-state imaging element mounted on a camera or the like is preferable.

The above-described solid-state imaging element is a solid-state imaging element containing the above-described cured film (light shielding film) according to the embodiment of the present invention.

Examples of an aspect in which the solid-state imaging element contains the cured film (light shielding film) include an aspect in which, on a substrate, a solid-state imaging element (CCD image sensor, CMOS image sensor, or the like) has light receiving elements which consist of a plurality of photodiodes and polysilicon or the like and constitute a light receiving area of the solid-state imaging element, and the cured film is provided on forming surface of the light receiving elements in the support (for example, a portion other than a light receiving section and/or a pixel for color adjustment, or the like) or on the opposite side of the forming surface.

In addition, for example, in a case where the cured film contained in the solid-state imaging element is disposed as a light attenuating film so that a part of light passes through the light attenuating film and then is incident on the light receiving elements, a dynamic range of the solid-state imaging element can be improved.

### [Image Display Device]

An image display device according to an embodiment of the present invention includes the cured film according to the embodiment of the present invention.

Examples of the form in which the image display device includes the cured film include a form in which the cured film is contained in a black matrix and a color filter including such a black matrix is used in an image display device.

Next, the black matrix and the color filter containing the black matrix will be described.

### <Black Matrix>

It is also preferable that the cured film according to the embodiment of the present invention is contained in the black matrix. The black matrix may be contained in an image display device such as a color filter, a solid-state imaging element, and a liquid crystal display device.

Examples of the black matrix include those described above; a black edge provided on a peripheral edge of an image display device such as a liquid crystal display device; a lattice-formed and/or striped black part between red, blue, and green pixels; and a dot-shaped and/or linear black pattern for shielding thin film transistor (TFT). With regard to the definition of the black matrix, for example, the description of “Dictionary of Liquid Crystal Display Manufacturing Apparatus Terms” by Taihei Kanno, 2nd edition, published by Nikkan Kogyo Shimbun, 1996, p. 64 can be referred to.

In order to improve display contrast and to prevent deterioration of image quality due to light current leakage in a case of an active matrix drive-type liquid crystal display device using a thin film transistor (TFT), the black matrix preferably has high light shielding properties (optical density (OD) of 3 or more).

As a method for manufacturing the black matrix, for example, the black matrix can be manufactured by the same method as the above-described method for manufacturing the cured film. Specifically, the patterned cured film (black matrix) can be manufactured by applying a composition to a substrate to form a composition layer, and performing exposure and development. The film thickness of the cured film used as the black matrix is preferably 0.1 to 4.0 μm.

A material of the substrate preferably has a transmittance of 80% or more with respect to visible light (wavelength of 400 to 800 nm). Examples of such a material include glass such as soda lime glass, non-alkali glass, quartz glass, and borosilicate glass; and plastics such as a polyester-based resin and a polyolefin-based resin, and from the viewpoint of chemical resistance and heat resistance, non-alkali glass, quartz glass, or the like is preferable.

### <Color Filter>

It is also preferable that the cured film according to the embodiment of the present invention is contained in the color filter.

Examples of the form in which the color filter includes the cured film include a color filter including a substrate and the above-described black matrix. That is, examples thereof include a color filter including colored pixels of red, green, and blue, which are formed in the opening portion of the black matrix formed on a substrate.

More specifically, the above-described cured film is disposed inside, for example, a color filter having subpixels. The subpixels include, for example, a red subpixel, a green subpixel, a blue subpixel, and the like.

A size (length of one side) of the subpixel in the color filter on which the cured film is disposed is preferably 15 μm or less, more preferably 10 μm or less, and still more preferably 5 μm or less. The lower limit thereof is not particularly limited, but is usually 0.5 μm or more. A shape of the subpixel is preferably a quadrangular shape. In a case of the quadrangular shape, the length of each side is preferably 15 μm or less.

The cured film is disposed inside the color filter, but a position thereof is not particularly limited. Examples thereof include an aspect in which the subpixel (red subpixel, green subpixel, or blue subpixel) is disposed on the cured film. That is, it is preferable that the cured film is disposed so as to be in contact with the subpixel (at least one of a red subpixel, a green subpixel, or a blue subpixel).

### <Image Display Device>

A color filter including the cured film obtained from the composition according to the embodiment of the present invention can be adopted to various uses, and examples thereof include a color filter of a display device (organic EL display device (OLED), liquid crystal display device, or the like) and a color filter of a solid-state imaging element.

Hereinafter, one embodiment of an organic EL display device including the color filter including the cured film according to the present invention will be described with reference to the drawing.

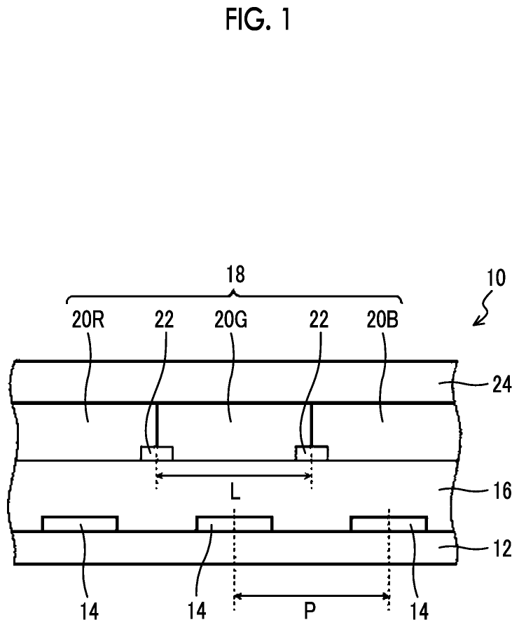

FIG. 1 shows a cross-sectional view of one embodiment of the organic EL display device including the color filter including the cured film according to the present invention. An organic EL display device 10 includes a substrate 12, a plurality of organic EL elements 14 arranged on the substrate 12 in a matrix, a protective layer 16 covering the organic EL elements 14, a color filter 18 disposed on the protective layer 16, and a sealing substrate 24 disposed on the color filter 18. The color filter 18 has a square red subpixel (red region) 20R, a square green subpixel (green region) 20G, a square blue subpixel (blue region) 20B, and two rectangular cured films 22. One cured film 22 is disposed between the red subpixel 20R and the green subpixel 20G, and the other cured film 22 is disposed between the green subpixel 20G and the blue subpixel 20B. That is, each subpixel is disposed on the cured film. In addition, the cured film is located between each subpixel.

The subpixel is intended to be each point of a single color of RGB constituting one pixel.

Each subpixel of the organic EL display device 10 generates light of any of three primary colors (red, green, and blue) by combining the plurality of organic EL elements 14, which generates white light, and the color filter 18. A pitch (intercenter distance) P of the plurality of organic EL elements 14 may be, for example, 30 μm or less, and specifically, for example, approximately 2 to 3 μm. That is, the organic EL display device may be a so-called micro display (micro OLED) in which dimensions of the organic EL elements 14 extremely small.

A thickness of the protective layer 16 is, for example, 0.5 to 10 μm. The protective layer 16 is composed of silicon nitride (SiN).

The sealing substrate 24 seals the organic EL elements, and is composed of a material such as transparent glass.

Each subpixel (red subpixel 20R, green subpixel 20G, and blue subpixel 20B) in the color filter 18 is square, and from the viewpoint of miniaturization, a length of one side thereof is 15 μm or less, preferably 10 μm or less and more preferably 5 μm or less. The lower limit thereof is not particularly limited, but is usually 0.5 μm or more due to manufacturing problems.

Although the aspect of the square subpixel is shown in FIG. 1, the aspect is not limited to this aspect, and may be, for example, a quadrangular shape or a rectangular shape. In a case of the rectangular shape, a length of a long side is preferably 15 μm or less.

The cured film 22 is a rectangular layer disposed between each subpixel and extending parallel to the interface between each subpixel. The shape of the cured film 22 is not limited to the embodiment shown in FIG. 1, and may be in any embodiment.

In addition, although the cured film 22 exists over two subpixels in the embodiment in FIG. 1, a position thereof is not particularly limited as long as it is disposed in the color filter.

### EXAMPLES

Hereinbelow, the present invention will be described in more detail with reference to Examples. The materials, the amounts and proportions of the materials used, the details of treatments, the procedure of treatments, and the like shown in the following Examples can be appropriately modified as long as the gist of the present invention is maintained. Therefore, the scope of the present invention should not be construed as being limited to Examples shown below.

### Examples 1 to 21

### [Production of Composition]

Hereinafter, each component used in a preparation of a composition will be described.

### [Dispersion Liquid]

A dispersion liquid was prepared by a method shown below. The dispersion liquid is used in the subsequent stage to prepare the composition.

### <Titanium Black Dispersion Liquid A>

The following raw materials were subjected to a dispersion treatment with NPM Pilot manufactured by Shinmaru Enterprises Corporation to obtain a titanium black dispersion liquid A (also simply referred to as a “dispersion liquid A”).

Titanium black (T-1) (details will be described later): 25 parts by mass
30% by mass PGMEA solution of resin (X-1) (pigment dispersant): 25 parts by mass
PGMEA: 23 parts by mass
Butyl acetate: 27 parts by mass

A structure of the above-described resin (X-1) is as follows. The weight-average molecular weight thereof was 30000. In addition, a number attached to each repeating unit indicate a molar ratio of each unit.

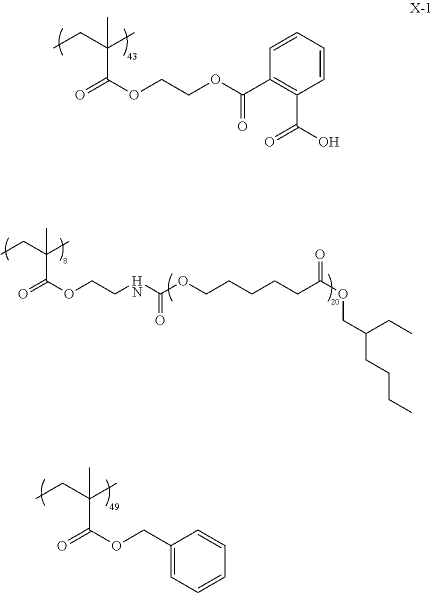

PGMEA means propylene glycol monomethyl ether acetate.

In addition, the 30% by mass PGMEA solution of the resin (X-1) is intended to be a solution in which the resin (X-1) is dissolved in PGMEA so that the content of the resin (X-1) is 30% by mass with respect to the total mass of the solution. Hereinafter, the description “(numerical character) % by mass (solvent name) solution of (substance name)” is based on the same intention.

### Production of Titanium Black (T-1)

Titanium oxide MT-150A (trade name, manufactured by TAYCA CORPORATION) having an average particle diameter of 15 nm (100 g), silica particles AEROSIL (registered trademark) 300/30 (manufactured by EVONIK) having a BET surface area of 300 m²/g (25 g), and a dispersant DISPERBYK-190 (trade name, manufactured by BYK Chemie) (100 g) were weighed, and these compounds were added to ion-exchanged water (71 g) to obtain a mixture. Thereafter, using MAZERSTAR KK-400W manufactured by KURABO, a uniform mixture aqueous solution was obtained by treating the mixture at a revolution speed of 1360 rpm and a rotation speed of 1047 rpm for 20 minutes. This aqueous solution was filled in a quartz container and heated to 920° C. in an oxygen atmosphere using a small rotary kiln (manufactured by Motoyama Co., Ltd.). Thereafter, the atmosphere in the small rotary kiln was replaced with nitrogen, and by flowing ammonia gas at 100 mL/min for 5 hours at the same temperature, a nitrogen reduction treatment was performed. After finishing the nitrogen reduction treatment, the recovered powder was pulverized in a mortar, thereby obtaining a powdered titanium black (T-1) including Si atom and having a specific surface area of 73 m²/g.

### <Titanium Black Dispersion Liquid B>

A titanium black dispersion liquid B (also simply referred to as a “dispersion liquid B”) was produced in the same manner as in the titanium black dispersion liquid A, except that the 30% by mass PGMEA solution of the resin (X-1) (pigment dispersant) was changed to a 30% by mass PGMEA solution of a resin (X-2) (pigment dispersant).

A structure of the resin (X-2) is as follows. The weight-average molecular weight thereof was 18000.

In addition, a number attached to each repeating unit indicate a molar ratio of each unit. In addition, in the following structure, x and y represent the repetition number, x/y=83.2/16.8, and x+y is 20.

The resin (X-2) corresponds to a resin containing a repeating unit having a graft chain and a repeating unit having an ethylenically unsaturated group.

A content of the ethylenically unsaturated group in the resin (X-2) is 0.45 mmol/g.

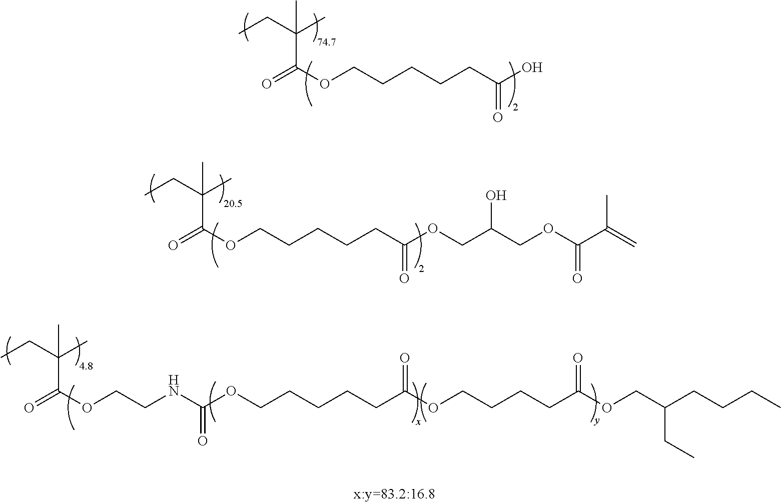

### <Carbon Black (CB) Dispersion Liquid C>

A dispersion obtained by mixing the following materials was further sufficiently stirred with a stirrer to perform pre-mixing. Further, the dispersion was subjected to a dispersion treatment using an Ultra Apex Mill UAM015 manufactured by KOTOBUKI INDUSTRIES CO., LTD. under dispersion conditions described later to obtain a dispersion liquid. After the completion of the dispersion, beads and the dispersion liquid were separated with a filter to obtain a CB dispersion liquid C (also simply referred to as a “dispersion liquid C”).

Coated carbon black (details will be described later): 20 parts by mass
DISPERBYK-167 (pigment dispersant, manufactured by BYK Chemie, solid content: 52% by mass): 8.7 parts by mass
Solsperse 12000 (pigment derivative, manufactured by Lubrizol Corporation): 1 part by mass
PGMEA: amount such that the solid content of the CB dispersion liquid C was 35% by mass

### Dispersion Conditions

Bead size: φ 0.05 mm

Bead filling rate: 65 vol %

Circumferential speed of mill: 10 m/sec

Circumferential speed of separator: 11 m/s

Amount of mixed solution subjected to dispersion treatment: 15.0 g

Circulation flow rate (pump supply rate): 60 kg/hour

Temperature of treatment liquid: 20° C. to 25° C.

Coolant: tap water (5° C.)

Inner volume of annular passage of beads mill: 2.2 L

Number of passes: 84 passes

### Production of Coated Carbon Black

Carbon black was produced by an ordinary oil furnace method. However, ethylene bottom oil having a small amount of Na, a small amount of Ca, and a small amount of S were used as stock oil, and combustion was performed using a gas fuel. Further, pure water treated with an ion exchange resin was used as reaction stop water.

The obtained carbon black (540 g) was stirred together with pure water (14500 g) using a homomixer at 5,000 to 6,000 rpm for 30 minutes to obtain a slurry. The slurry was transferred to a container with a screw-type stirrer, and toluene (600 g) in which an epoxy resin “EPIKOTE 828” (manufactured by Japan Epoxy Resins Co., Ltd.) (60 g) was dissolved was added thereto little by little while performing mixing at approximately 1,000 rpm. In approximately 15 minutes, the total amount of the carbon black dispersed in water was transferred to the toluene side, thereby forming grains having a particle size of approximately 1 mm.

Next, draining was performed with a wire mesh having 60 meshes, and then the separated grains were placed in a vacuum dryer and dried at 70° C. for 7 hours to remove toluene and water. The resin-coating amount of the obtained coated carbon black was 10% by mass with respect to the total amount of the carbon black and the resin.

### [Resin (Alkali-Soluble Resin)]

The following resin (alkali-soluble resin) was used.
P-1: resin having the following structure (solid content: 40% by mass, solvent:

PGMEA; referring to the following structure as a structure of the solid content (resin), in which a compositional ratio shown in the structure is a molar ratio; weight-average molecular weight of resin: 11000, acid value of resin: 70 mgKOH/g)

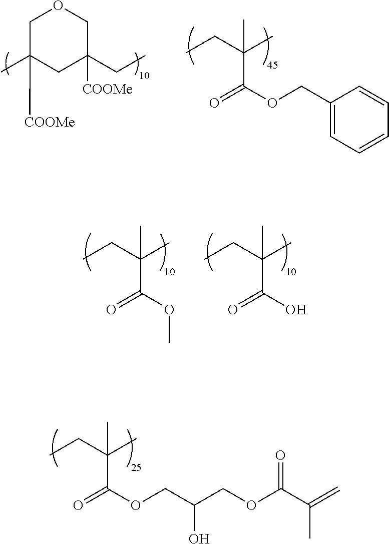

### [Polymerizable Compound]

The following polymerizable compounds were used.
A-TMMT: NK ESTER A-TMMT (trade name, manufactured by Shin-Nakamura Chemical Co., Ltd., pentaerythritol tetraacrylate)
DPHA: KAYARAD DPHA (trade name, manufactured by Nippon Kayaku Co., Ltd., dipentaerythritol hexaacrylate)
M-350: ARONIX M-350 (trade name, manufactured by TOAGOSEI CO., LTD., compound represented by “[CH₂═CHCO—(OC₂H₄)ₙ—OCH₂]₃—CCH₂CH₃ (n≈1)”

### [Photopolymerization Initiator]

The following photopolymerization initiators were used.

<Photopolymerization Initiator a>
IRGACURE OXE01 (trade name, manufactured by BASF Japan)
IRGACURE OXE02 (trade name, manufactured by BASF Japan)
I-1: photopolymerization initiator of Formula (I-1)

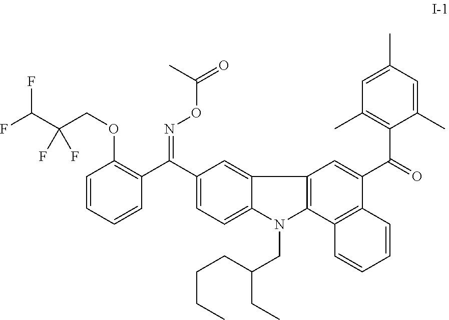 [SMILES: CCCCC(CC)CN(c1ccc(/C(=N\OC(C)=O)c2ccccc2OCC(F)(F)C(F)F)cc1C)c1c(C)cc(C(=O)c2c(C)cc(C)cc2C)c2ccccc12]

IRGACURE OXE01, IRGACURE OXE02, and I-1 are all oxime compounds.

<Photopolymerization Initiator b>
Omnirad 2959: trade name, manufactured by IGM Resins B.V., 1-[4-(2-hydroxyethoxy)-phenyl]-2-hydroxy-methylpropanone
Omnirad 184: trade name, manufactured by IGM Resins B.V., 1-hydroxycyclohexylphenyl ketone

### [Surfactant]

The following surfactant was used.
W-1: surfactant represented by the following formula (weight-average molecular weight=15000)

Here, in the following formula, structural units represented by Formulae (A) and (B) are 62 mol % and 38 mol %, respectively. In the structural unit represented by Formula (B), a, b, and c each satisfy relationships of a+c=14 and b=17.

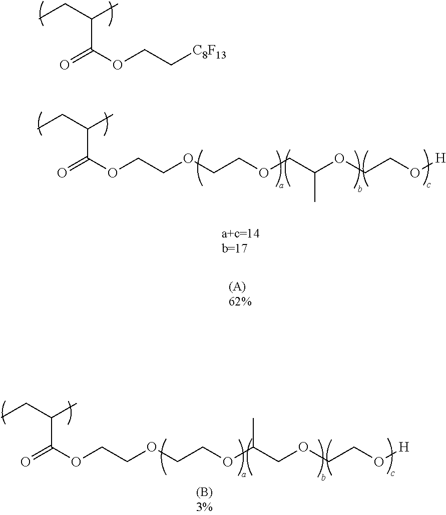

### [Ultraviolet Absorber]

UV-1: compound shown below

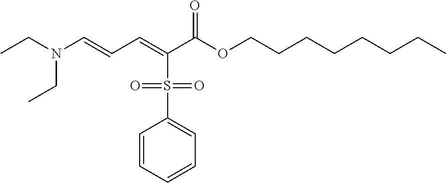 [SMILES: CCCCCCCCOC(=O)/C(=C/C=C/N(CC)CC)S(=O)(=O)c1ccccc1]

### [Polymerization Inhibitor]

The following polymerization inhibitor was used.
p-Methoxyphenol

### [Solvent]

The following organic solvents were used.
PGMEA: propylene glycol monomethyl ether acetate
Cyclopentanone

### [Preparation of Composition (Coloring Composition)]

Each of the above-described components was mixed in the formulation shown in the tables below and stirred, and the obtained mixture was filtered through a nylon filter (manufactured by Nihon Pall Corporation) having a pore diameter of 0.45 μm to prepare each of compositions of Examples or Comparative Examples.

The formulation amount of each component shown in the tables below is part by mass. In addition, in a case where each component is a mixture, the formulation amount (part by mass) as the added mixture is shown. For example, the alkali-soluble resin P-1 was added in a form of a PGMEA solution having a solid content of 40% by mass, and the value described as the amount of P-1 added in the tables below are the addition amounts of the PGMEA solution having a solid content of 40% by mass as a whole.

### [Evaluation]

The compositions of each example were evaluated as shown below.

[Production of Substrate with Cured Film]

Each composition was applied to a glass substrate using a spin coater such that a finished film thickness after drying was 1.0 and dried on a hot plate at 100° C. for 2 minutes (composition layer-forming step).

Thereafter, using an ultra-high pressure mercury lamp, i-rays exposure was performed under conditions of an exposure illuminance of 20 mW/cm² (first exposing step). In this case, an irradiation amount was adjusted so that the irradiation amount of i-rays was 1 J/cm².

Next, using an ultraviolet photoresist curing device (UMA-802-HC-552, manufactured by USHIO INC.), exposure was performed with an exposure amount of 3000 mJ/cm² (second exposing step). In the light irradiated using the above-described ultraviolet photoresist curing device, in a case where an intensity of the maximum wavelength in a wavelength region of 330 to 500 nm was set as 100%, the intensity of the maximum wavelength in a wavelength region of 200 to 315 nm was 50% or more.

Through the above-described steps, a substrate with a cured film for evaluation was obtained.

### [Evaluation of Absorbance (Maximum Absorbance/Minimum Absorbance)]

Using a spectrophotometer (reference: glass substrate) of ultraviolet-visible-near infrared spectrophotometer UV3600 (manufactured by Shimadzu Corporation), a light absorbance of the obtained cured film in a wavelength range of 400 to 700 nm was measured to calculate a ratio (maximum absorbance/minimum absorbance) of the maximum absorbance and the minimum absorbance of the cured film.

### [Evaluation of Stability of Spectral Characteristics]

A high-temperature and high-humidity treatment was carried out in which the substrate with a cured film was exposed to the conditions of 85° C. and 85% for 1000 hours. Spectroscopic transmittance (simply also referred to as a “transmittance”) of the cured film before and after the treatment was measured.

In a wavelength range of 400 to 1100 nm, a rate of change in transmittance was calculated for each measurement wavelength based on the following expression, and the maximum value among those rates of change was used as an indicator for evaluation as follows. In a case where the evaluation value is 2 or more, it can be said that a stability of spectral characteristics is superior to that in the related art.

Rate of change (%)=(Transmittance before treatment−Transmittance after treatment|)÷Transmittance before treatment×100
5: rate of change as an indicator was 1% or less.
4: rate of change as an indicator was more than 1% and 2% or less.
3: rate of change as an indicator was more than 2% and 3% or less.
2: rate of change as an indicator was more than 3% and 4% or less.
1: rate of change as an indicator was more than 4%.

### [Results]

The following tables show the formulation of solid content of the composition used in each test example, characteristics, and test results.

TABLE 1

| | | | Example | Example | Example | Example | Example | Example | Example | Example |
|---|---|---|---|---|---|---|---|---|---|---|
| | | | 1 | 2 | 3 | 4 | 5 | 6 | 7 | 8 |
| Formulation | Dispersion | A | 30 | 30 | 30 | 30 | 30 | 30 | 30 | 30 |
| | liquid | B | | | | | | | | |
| | | C | | | | | | | | |
| | Polymerizable | A-TMMT | 7.3 | 7.3 | 7.3 | 7.3 | 7.3 | 7.3 | 7.3 | 10.0 |
| | compound | DPHA | | | | | | | | |
| | | M-350 | | | | | | | | |
| | Resin | P-1 | 11.0 | 11.8 | 11.4 | 9.8 | 8.0 | 7.0 | 6.0 | 4.2 |
| | Photopolymerization | IRGACURE | 1.50 | 1.50 | 1.50 | 1.50 | 1.50 | 1.50 | 1.50 | 1.50 |
| | initiator a | OXE01 | | | | | | | | |
| | | IRGACURE | | | | | | | | |
| | | OXE02 | | | | | | | | |
| | | I-1 | | | | | | | | |
| | Photopolymerization | Omnirad 2959 | 1.00 | 0.70 | 0.85 | 1.50 | 2.20 | 2.60 | 3.00 | 1.00 |
| | initiator b | Omnirad 184 | | | | | | | | |
| | Surfactant | W-1 | 0.04 | 0.04 | 0.04 | 0.04 | 0.04 | 0.04 | 0.04 | 0.04 |
| | Ultraviolet absorber | UV-1 | 1.00 | 1.00 | 1.00 | 1.00 | 1.00 | 1.00 | 1.00 | 1.00 |
| | Polymerization | p-Methoxyphenol | 0.010 | 0.010 | 0.010 | 0.010 | 0.010 | 0.010 | 0.010 | 0.010 |
| | inhibitor | | | | | | | | | |
| | Solvent | PGMEA | 35.43 | 34.90 | 35.15 | 36.10 | 37.20 | 37.80 | 38.40 | 39.50 |
| | | Cyclohexanone | 12.75 | 12.75 | 12.75 | 12.75 | 12.75 | 12.75 | 12.75 | 12.75 |

| | | | | | | | | | |
|---|---|---|---|---|---|---|---|---|---|
| Character- | Content of photopolymerization | 66.7 | 46.7 | 56.7 | 100.0 | 146.7 | 173.3 | 200.0 | 66.7 |
| istics | initiator b with respect to 100 parts | | | | | | | | |
| | by mass of photopolymerization | | | | | | | | |
| | initiator a (part by mass) | | | | | | | | |
| | Content of polymerizable compound | 97 | 97 | 97 | 97 | 97 | 97 | 97 | 133 |
| | with respect to 100 parts by mass | | | | | | | | |
| | of black colorant (part by mass) | | | | | | | | |
| Result | Maximum absorbance/minimum | 1.87 | 1.87 | 1.87 | 1.87 | 1.87 | 1.87 | 1.87 | 1.87 |
| | absorbance | | | | | | | | |
| | Stability of spectral characteristics | 5 | 3 | 4 | 5 | 5 | 5 | 3 | 5 |

TABLE 2

| | | | Example | Example | Example | Example | Example | Example | Example | Example |
|---|---|---|---|---|---|---|---|---|---|---|
| | | | 9 | 10 | 11 | 12 | 13 | 14 | 15 | 16 |
| Formulation | Dispersion | A | 30 | 40 | 35 | 20 | 15 | 15 | 30 | 30 |
| | liquid | B | | | | | | | | |
| | | C | | | | | | | | |
| | Polymerizable | A-TMMT | 6.0 | 7.3 | 7.3 | 7.3 | 7.3 | 9.0 | 7.3 | 7.3 |
| | compound | DPHA | | | | | | | | |
| | | M-350 | | | | | | | | |
| | Resin | P-1 | 14.2 | 2.8 | 7.0 | 19.0 | 23.2 | 19.0 | 11.0 | 11.0 |
| | Photopolymerization | IRGACURE | 1.50 | 1.50 | 1.50 | 1.50 | 1.50 | 1.50 | | |
| | initiator a | OXE01 | | | | | | | | |
| | | IRGACURE | | | | | | | 1.50 | |
| | | OXE02 | | | | | | | | |
| | | I-1 | | | | | | | | 1.50 |
| | Photopolymerization | Omnirad 2959 | 1.00 | 1.00 | 1.00 | 1.00 | 1.00 | 1.00 | 1.00 | 1.00 |
| | initiator b | Omnirad 184 | | | | | | | | |
| | Surfactant | W-1 | 0.04 | 0.04 | 0.04 | 0.04 | 0.04 | 0.04 | 0.04 | 0.04 |
| | Ultraviolet absorber | UV-1 | 1.00 | 1.00 | 1.00 | 1.00 | 1.00 | 1.00 | 1.00 | 1.00 |
| | Polymerization | p-Methoxyphenol | 0.010 | 0.010 | 0.010 | 0.010 | 0.010 | 0.010 | 0.010 | 0.010 |
| | inhibitor | | | | | | | | | |
| | Solvent | PGMEA | 33.50 | 37.40 | 38.20 | 37.40 | 38.20 | 40.70 | 35.43 | 35.43 |
| | | Cyclohexanone | 12.75 | 8.95 | 8.95 | 12.75 | 12.75 | 12.75 | 12.75 | 12.75 |

| | | | | | | | | | |
|---|---|---|---|---|---|---|---|---|---|
| Character- | Content of photopolymerization | 66.7 | 66.7 | 66.7 | 66.7 | 66.7 | 66.7 | 66.7 | 66.7 |
| istics | initiator b with respect to 100 parts | | | | | | | | |
| | by mass of photopolymerization | | | | | | | | |
| | initiator a (part by mass) | | | | | | | | |
| | Content of polymerizable compound | 80 | 73 | 83 | 146 | 195 | 240 | 97 | 97 |
| | with respect to 100 parts by mass | | | | | | | | |
| | of black colorant (part by mass) | | | | | | | | |
| Result | Maximum absorbance/minimum | 1.87 | 1.90 | 1.87 | 1.80 | 1.70 | 1.75 | 1.87 | 1.87 |
| | absorbance | | | | | | | | |
| | Stability of spectral characteristics | 4 | 3 | 5 | 5 | 4 | 3 | 5 | 5 |

TABLE 3

| | | | | | | | | Compar- | Compar- | Compar- |
|---|---|---|---|---|---|---|---|---|---|---|
| | | | Example | Example | Example | Example | Example | ative | ative | ative |
| | | | 17 | 18 | 19 | 20 | 21 | Example 1 | Example 2 | Example 3 |
| Formulation | Dispersion | A | 30 | 30 | 30 | | | | | |
| | liquid | B | | | | 30 | | | | |
| | | C | | | | | 27.35 | 27.35 | 27.35 | 27.35 |
| | Polymerizable | A-TMMT | 7.3 | | | 7.3 | 6.6 | 6.6 | 6.6 | 6.6 |
| | compound | DPHA | | 7.3 | | | | | | |
| | | M-350 | | | 7.3 | | | | | |
| | Resin | P-1 | 11.0 | 11.0 | 11.0 | 11.0 | 13.2 | 13.2 | 13.2 | 13.2 |
| | Photopolymerization | IRGACURE | 1.50 | 1.50 | 1.50 | 1.50 | 1.50 | 1.50 | 1.50 | 1.50 |
| | initiator a | OXE01 | | | | | | | | |
| | | IRGACURE | | | | | | | | |
| | | OXE02 | | | | | | | | |
| | | I-1 | | | | | | | | |
| | Photopolymerization | Omnirad 2959 | | 1.00 | 1.00 | 1.00 | 1.00 | | 0.67 | 3.01 |
| | initiator b | Omnirad 184 | 1.00 | | | | | | | |
| | Surfactant | W-1 | 0.04 | 0.04 | 0.04 | 0.04 | 0.04 | 0.04 | 0.04 | 0.04 |
| | Ultraviolet absorber | UV-1 | 1.00 | 1.00 | 1.00 | 1.00 | 1.00 | 1.00 | 1.00 | 1.00 |
| | Polymerization | p-Methoxyphenol | 0.010 | 0.010 | 0.010 | 0.010 | 0.010 | 0.010 | 0.010 | 0.010 |
| | inhibitor | | | | | | | | | |
| | Solvent | PGMEA | 35.43 | 35.43 | 35.43 | 35.43 | 36.55 | 37.55 | 36.88 | 34.54 |
| | | Cyclohexanone | 12.75 | 12.75 | 12.75 | 12.75 | 12.75 | 12.75 | 12.75 | 12.75 |

| | | | | | | | | | |
|---|---|---|---|---|---|---|---|---|---|
| Character- | Content of photopolymerization | 66.7 | 66.7 | 66.7 | 66.7 | 66.7 | 0 | 44.7 | 200.7 |
| istics | initiator b with respect to 100 parts | | | | | | | | |
| | by mass of photopolymerization | | | | | | | | |
| | initiator a (part by mass) | | | | | | | | |
| | Content of polymerizable compound | 97 | 97 | 97 | 97 | 88 | 88 | 88 | 88 |
| | with respect to 100 parts by mass | | | | | | | | |
| | of black colorant (part by mass) | | | | | | | | |
| Result | Maximum absorbance/minimum | 1.87 | 1.82 | 1.95 | 1.90 | 1.99 | 1.87 | 1.87 | 1.87 |
| | absorbance | | | | | | | | |
| | Stability of spectral characteristics | 5 | 5 | 4 | 5 | 5 | 1 | 1 | 1 |

From the results shown in the tables, it was confirmed that the problems of the present invention can be solved by using the composition according to the embodiment of the present invention.

On the other hand, the stability of spectral characteristics of the cured film formed of the composition of Comparative Examples was insufficient.

Among these, from the viewpoint that the effect of the present invention is more excellent, it is confirmed that the content of the photopolymerization initiator b is preferably 50.0 to 180.0 parts by mass and more preferably 60.0 to 180.0 parts by mass with respect to 100.0 parts by mass of the content of the photopolymerization initiator a (refer to the comparison of the results of Examples 1 to 7).

From the viewpoint that the effect of the present invention is more excellent, it is confirmed that the content of the polymerizable compound is preferably 75 to 200 parts by mass and more preferably 82 to 150 parts by mass with respect to 100 parts by mass of the content of the black colorant (refer to the comparison of the results of Examples 1 and 8 to 14).

From the viewpoint that the effect of the present invention is more excellent, it is confirmed that the polymerizable compound preferably contains 4 or more ethylenically unsaturated bonds (refer to the comparison of the results of Examples 1, 18, and 19).

### Example 22

In the above-described [Production of substrate with cured film] using the composition of Example 1, after performing up to the second exposing step, the cured film in the obtained substrate with a cured film was heated at a heating temperature of 110° C. for 10 minutes using a hot plate (heating step). In a case where the cured film after heating was evaluated in the same manner as in other Examples, the evaluation value of the stability of spectral characteristics was 5. In addition, the ratio of the maximum absorbance to the minimum absorbance of the obtained cured film at a wavelength of 400 to 700 nm was the same as that of the cured film in Example 1.

### Example 23

A cured film after heating was obtained in the same manner as in Example 22, except that the heating step was carried out in a heating tank under a nitrogen atmosphere where nitrogen was introduced while exhausting air, and the heating temperature was changed to 100° C. In a case where the obtained cured film after heating was evaluated in the same manner as in other Examples, the evaluation value of the stability of spectral characteristics was 5. In addition, the ratio of the maximum absorbance to the minimum absorbance of the obtained cured film at a wavelength of 400 to 700 nm was the same as that of the cured film in Example 1.

The concentration of nitrogen gas in the heating tank during the heating step was 99% by volume or more.

### Examples 24 to 27

In addition, a composition was produced in which 3% by mass of the titanium black (T-1) included in the composition of Example 1 was replaced with Solvent Black 3 (manufactured by Tokyo Chemical Industry Co., Ltd.), and in a case where the composition was evaluated in the same manner as the composition of Example 1, the evaluation value of the stability of spectral characteristics of the obtained cured film was 5 (Example 24).

A composition was produced in which 1 part by mass of Pigment Blue 15:6 was added with respect to 100 parts by mass of the total solid content included in the composition of Example 1, and in a case where the composition was evaluated in the same manner as the composition of Example 1, the evaluation value of the stability of spectral characteristics of the obtained cured film was 5 (Example 25).

A composition was produced in which 1 part by mass of Pigment Yellow 139 was added with respect to 100 parts by mass of the total solid content included in the composition of Example 1, and in a case where the composition was evaluated in the same manner as the composition of Example 1, the evaluation value of the stability of spectral characteristics of the obtained cured film was 5 (Example 26).

A composition was produced in which 1 part by mass of Pigment Red 254 was added with respect to 100 parts by mass of the total solid content included in the composition of Example 1, and in a case where the composition was evaluated in the same manner as the composition of Example 1, the evaluation value of the stability of spectral characteristics of the obtained cured film was 5 (Example 27).

The ratio of the maximum absorbance to the minimum absorbance of the cured films formed of the compositions of Examples 24 to 27 at a wavelength of 400 to 700 nm was in a range of 1.40 to 2.00.

Even in a case of excluding the surfactant in Example 1, the same effect is obtained. Even in a case of excluding the polymerization inhibitor in Example 1, the same effect is obtained. In a case where the titanium black (T-1) in Example 1 was replaced with titanium black containing no Si atom, the result that the stability of spectral characteristics was 4 is obtained. In a case where the coated carbon black in Example 21 was replaced with uncoated carbon black, the result that the stability of spectral characteristics was 4 is obtained.

The ratio of the maximum absorbance to the minimum absorbance of the cured film formed of a composition in which the formulation was changed as described above at a wavelength of 400 to 700 nm is in a range of 1.40 to 2.00.

### EXPLANATION OF REFERENCES

10: organic EL display device

12: substrate

14: organic EL element

16: protective layer

18: color filter

20R: red subpixel

20G: green subpixel

20B: blue subpixel

22: cured film

24: sealing substrate

What is claimed is:

1. A coloring composition comprising:
a black colorant;
a polymerizable compound; and
a photopolymerization initiator,
wherein the photopolymerization initiator includes a photopolymerization initiator a in which a light absorption coefficient at 365 nm in methanol is more than 1.0×10² mL/gcm and a photopolymerization initiator b in which a light absorption coefficient at 365 nm in methanol is 1.0×10² mL/gcm or less and a light absorption coefficient at 254 nm in methanol is 1.0×10³ mL/gcm or more,
a content of the photopolymerization initiator b is 45.0 to 200.0 parts by mass with respect to 100.0 parts by mass of a content of the photopolymerization initiator a, and
a ratio of a maximum absorbance to a minimum absorbance of a coloring cured film obtained by curing the coloring composition at a wavelength of 400 to 700 nm is 1.00 to 2.50.

2. The coloring composition according to claim 1,
wherein the black colorant is one or more kinds selected from the group consisting of a metal nitride, a metal oxynitride, and carbon black.

3. The coloring composition according to claim 1,
wherein the black colorant is surface-coated particles.

4. The coloring composition according to claim 1,
wherein a content of the polymerizable compound is 70 to 250 parts by mass with respect to 100 parts by mass of a content of the black colorant.

5. The coloring composition according to claim 1,
wherein a content of the polymerizable compound is 75 to 200 parts by mass with respect to 100 parts by mass of a content of the black colorant.

6. The coloring composition according to claim 1,
wherein the photopolymerization initiator a is an oxime compound.

7. The coloring composition according to claim 1,
wherein the photopolymerization initiator b is a hydroxyalkylphenone compound.

8. The coloring composition according to claim 1,
wherein the content of the photopolymerization initiator b is 50.0 to 180.0 parts by mass with respect to 100.0 parts by mass of the content of the photopolymerization initiator a.

9. The coloring composition according to claim 1,
wherein the polymerizable compound contains 4 or more ethylenically unsaturated groups.

10. The coloring composition according to claim 1,
wherein the coloring composition is a light-shielding coloring composition used for manufacturing an organic EL display device.

11. A method for manufacturing a coloring cured film, comprising:
a composition layer-forming step of applying the coloring composition according to claim 1 to a substrate to form a composition layer;
a first exposing step of pre-curing the composition layer by exposing the composition layer to be irradiated with an actinic ray or a radiation; and
a second exposing step of post-curing the composition layer by exposing the pre-cured composition layer to be further irradiated with an actinic ray or a radiation to form a coloring cured film.

12. The method for manufacturing a coloring cured film according to claim 11,
wherein the actinic ray or the radiation used for the irradiation in the second exposing step is i-rays, and
an irradiation amount of the i-rays is 1 J/cm² or more.

13. The method for manufacturing a coloring cured film according to claim 11,
wherein the actinic ray or the radiation used for the irradiation in the second exposing step is ultraviolet rays.

14. The method for manufacturing a coloring cured film according to claim 11, further comprising:
a developing step of developing the pre-cured composition layer using a developer to obtain a composition layer having a patterned shape after the first exposing step and before the second exposing step.

15. The method for manufacturing a coloring cured film according to claim 11, further comprising:
a heating step of heating the coloring cured film after the second exposing step,
wherein, in the heating step, the coloring cured film is heated at 100° C. to 120° C. for 10 minutes or longer.

16. The method for manufacturing a coloring cured film according to claim 11, further comprising:
a heating step of heating the coloring cured film after the second exposing step,
wherein the heating step is performed under a nitrogen atmosphere.

17. A coloring cured film obtained by curing the coloring composition according to claim 1.

18. The coloring cured film according to claim 17,
wherein the coloring cured film has a patterned shape.

19. A color filter comprising:
the coloring cured film according to claim 17; and
one or more subpixels selected from the group consisting of a red subpixel, a green subpixel, and a blue subpixel.

20. An organic EL display device comprising:
the color filter according to claim 19.
